(19) United States
(12) Patent Application Publication
(10) Pub. No.: US 2026/0099637 A1
(43) Pub. Date: Apr. 9, 2026

(54) METHOD, SYSTEM AND COMPUTER PROGRAM PRODUCT FOR INTEGRATED CIRCUIT DESIGN

(71) Applicant: TAIWAN SEMICONDUCTOR MANUFACTURING COMPANY, LTD., Hsinchu (TW)

(72) Inventors: Yao-Jen HSIEH, Hsinchu (TW); Chih-Chieh WANG, Hsinchu (TW); Kai-Ming LIU, Hsinchu (TW)

(21) Appl. No.: 19/052,596

(22) Filed: Feb. 13, 2025

Related U.S. Application Data
(60) Provisional application No. 63/704,299, filed on Oct. 7, 2024.

(51) Int. Cl. G06F 30/12; G06F 30/323; G06F 30/398

(52) U.S. Cl. CPC G06F 30/12; G06F 30/323; G06F 30/398

(57) ABSTRACT

A method is executed at least partially by at least one processor and includes generating an integrated circuit (IC) layout corresponding to an IC schematic of an IC device. The IC device includes semiconductor devices arranged at a plurality of levels along a thickness direction of the IC device. The IC layout includes, for a semiconductor device among the semiconductor devices, a label feature indicating, among the plurality of levels, a corresponding level at which the semiconductor device is arranged. The method further includes generating a layout netlist corresponding to the IC layout, performing a layout versus schematic (LVS) check based on a source netlist corresponding to the IC schematic and the layout netlist, and modifying at least one of the IC layout or the IC schematic in response to the LVS check indicating an error.

### RELATED APPLICATION(S)

This application claims the benefit of U.S. Provisional Application No. 63/704,299, filed Oct. 7, 2024, which is herein incorporated by reference in its entirety.

### BACKGROUND

An integrated circuit (“IC”) device includes one or more semiconductor devices represented in an IC layout diagram (also referred to as “layout diagram”, “layout”, or “IC layout”). An IC layout is hierarchical and includes modules which carry out higher-level functions in accordance with the semiconductor device's design specifications. The modules are often built from a combination of cells, each of which represents one or more semiconductor devices configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. To reduce the sizes of IC devices, sometimes semiconductor devices are formed, or stacked, over each other.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a functional flow chart of an IC design flow, in accordance with some embodiments.

FIG. 2 is a functional flow chart of an IC design flow, in accordance with some embodiments.

FIG. 3 includes a schematic perspective view of a circuit region of an IC device, and example netlists corresponding to the circuit region, in accordance with some embodiments.

FIGS. 4A, 4B, 4C, 4D each include a schematic perspective view of a circuit region of an IC device, an example IC layout and an example netlist corresponding to the circuit region, in accordance with some embodiments.

FIGS. 5A, 5B each include a schematic perspective view of a circuit region of an IC device, an example IC layout and an example netlist corresponding to the circuit region, in accordance with some embodiments.

FIGS. 6A, 6B, 6C each include an example IC layout and an example netlist corresponding to a circuit region of an IC device, in accordance with some embodiments.

FIG. 7 includes an example IC layout and an example netlist corresponding to a circuit region of an IC device, in accordance with some embodiments.

FIGS. 8A, 8B, 8C are flowcharts of various methods, in accordance with some embodiments.

FIG. 9 is a block diagram of an electronic design automation (EDA) system in accordance with some embodiments.

FIG. 10 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As described herein, sometimes semiconductor devices are formed, or stacked, over each other to reduce the sizes of IC devices. This stacked structure includes multiple semiconductor devices arranged or stacked one on top another, and presents a challenge regarding how to accurately and/or efficiently represent the stacked semiconductor devices in a corresponding IC layout or netlist during the IC design process.

In some embodiments, an IC device comprises semiconductor devices arranged at a plurality of levels along a thickness direction of the IC device. For a semiconductor device of the IC device, a label feature is included in at least one of an IC layout or a netlist corresponding to the IC device to indicate a level, among the plurality of levels, at which the semiconductor device is arranged. In at least one embodiment, the level at which each semiconductor device in the IC device is arranged is indicated by a corresponding label feature included in at least one of the IC layout or the netlist. In an example, the netlist is a layout netlist generated based on the IC layout. In a further example, the netlist is a source netlist generated based on an IC schematic of the IC device. Using the source netlist and/or the layout netlist with label features indicating levels of semiconductor devices, one or more checks or verifications, such as a layout-versus-schematic (LVS) check, are performed during the IC design process. In some embodiments, a single IC layout file and a single netlist file are sufficient for an LVS check on a stacked structure including a plurality of levels of semiconductor devices. Compared to other approaches where levels of semiconductor devices are not indicated in an IC layout or a netlist, an LVS check, or a different layout verification, using a netlist with label features indicating levels of semiconductor devices is more accurate, systematic and/or efficient.

In some embodiments, several layout design methods of configuring IC layouts to include label features indicating levels of semiconductor devices are provided. In at least one embodiment, several netlist formats with label features indicating levels of semiconductor devices are provided. In some embodiments, any of the layout design methods is usable with any of the netlist formats. The provisions and/or combinations of several layout design method and/or netlist formats for indicating levels of semiconductor devices provide IC designers with flexibility and/or various approaches for resource management. Further advantages and/or effects are achievable in one or more embodiments as described herein.

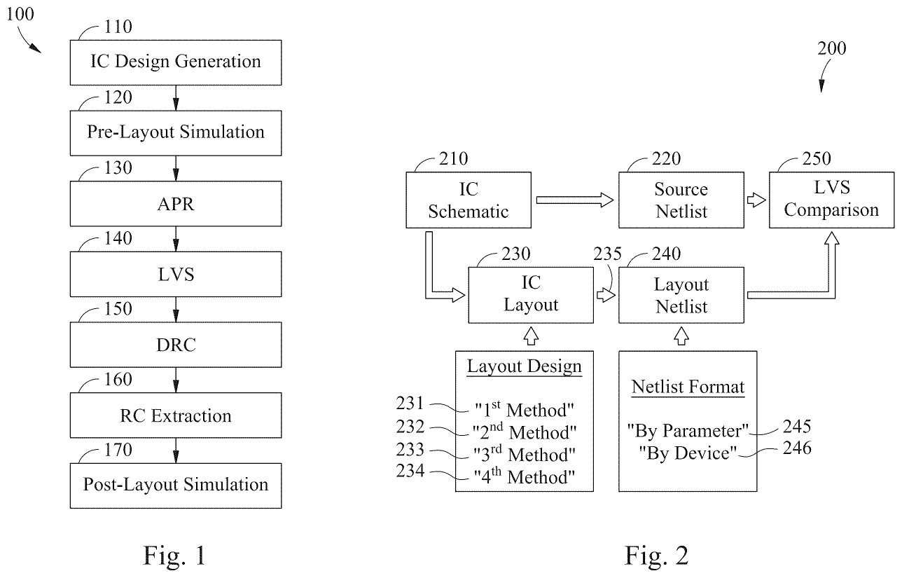

FIG. 1 is a functional flow chart of an IC design flow 100 in accordance with some embodiments.

In at least one embodiment, the IC design flow 100 utilizes one or more electronic design automation (EDA) tools (or systems) for testing a design of an IC device (sometimes simply referred to as “IC”) before manufacturing. The EDA tools, in some embodiments, comprise one or more sets of executable instructions for execution by at least one processor or controller or programmed computer to perform the indicated functionality. In at least one embodiment, the IC design flow 100 is performed by a design house of an IC manufacturing system discussed herein. In the example configuration in FIG. 1, the IC design flow 100 comprises operations 110-170.

At operation 110, a design of an IC is provided or generated, e.g., by a circuit designer. In some embodiments, the design of the IC includes an IC schematic, i.e., an electrical diagram, of the IC. In some embodiments, the IC schematic is generated or provided in the form of a schematic netlist, such as a Simulation Program with Integrated Circuit Emphasis (SPICE) netlist. Other data formats for describing the design are usable in some embodiments.

At operation 120, a pre-layout simulation is performed, e.g., by an EDA tool, on the design to determine whether the design meets a predetermined specification. If the design does not meet the predetermined specification, the IC is redesigned. In some embodiments, a SPICE simulation is performed on the SPICE netlist. Other simulation tools are usable, in place of or in addition to the SPICE simulation, in other embodiments.

At operation 130, a layout (or IC layout) of the IC is generated based on the design. The IC layout comprises the physical positions of various circuit elements (or devices) of the IC as well as the physical positions of various nets and vias interconnecting the circuit elements. In some embodiments, the IC layout is generated in the form of a Graphic Design System (GDS) file or GDSII file by an EDA tool. Other data formats for describing the IC layout of the IC are within the scope of various embodiments. For example, in one or more embodiments, the IC layout is generated and/or output in the form of an Open Artwork System Interchange Standard (OASIS) file, or a Design Framework II (DFII) file. For simplicity, non-limiting examples are provided herein for IC layouts included in GDS files.

In some embodiments, the IC layout is generated at operation 130 by an EDA tool or EDA system, such as an Automatic Placement and Routing (APR) tool. The APR tool receives the design of the IC in the form of a netlist as described herein, and performs a placement operation (or placement). For example, cells configured to provide pre-defined functions and having pre-designed layouts are stored in at least one library on at least one non-transitory computer-readable medium. The APR tool accesses various cells from the at least one library, and places the cells in an abutting manner to generate an IC layout corresponding to the IC schematic. Example cells include, but are not limited to, inverters, adders, multipliers, logic gates, phase lock loops (PLLs), flip-flops, multiplexers, memory cells, combinations thereof, or the like. Example logic gates include, but are not limited to, an AND, OR, NAND, NOR, XOR, INV, AND-OR-Invert (AOI), OR-AND-Invert (OAI), MUX, Flip-flop, BUFF, Latch, delay, clock cells, or the like. In some embodiments, a cell includes one or more active or passive circuit elements. Examples of active circuit elements (sometimes referred to as “semiconductor devices”) include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), FinFETs, planar MOS transistors with raised source/drain, nanosheet FETs, nanowire FETs, or the like. Examples of diodes include, but are not limited to, varactors, or the like. Examples of passive circuit elements include, but are not limited to, capacitors, inductors, fuses, and resistors.

The APR tool then performs a routing operation (or routing) to route various nets and vias interconnecting the placed circuit elements. Examples of nets include, but are not limited to, conductive pads, conductive patterns, and conductive redistribution layers, or the like. The routing operation is performed to ensure that the routed interconnections satisfy a set of constraints. After the routing operation, the APR tool outputs the IC layout including the placed circuit elements and the routed nets and vias, in a GDS file as described herein. Nets and vias are commonly referred to herein as routing features. The described APR operation is an example. Other arrangements are within the scope of various embodiments. For example, in one or more embodiments, one or more of the described operations are omitted.

At operation 140, a layout-versus-schematic (LVS) check, is performed. The LVS check is performed to ensure that the generated IC layout corresponds to the design. Specifically, an LVS checking tool, i.e., an EDA tool or EDA system, recognizes, or extracts, electrical components as well as connections therebetween from the patterns of the generated IC layout. The LVS checking tool then generates a layout netlist representing the recognized electrical components and connections. The layout netlist generated from the IC layout is compared, by the LVS checking tool, with the schematic netlist (sometimes referred to as “source netlist”) of the design. If the two netlists match, e.g., within a matching tolerance, the LVS check is passed. Otherwise, correction is made to at least one of the IC layout or the design by returning the process to operation 110 and/or operation 130. Other verification processes are usable in some embodiments.

At operation 150, a design rule check (DRC) is performed, e.g., by an EDA tool, on the GDS file including the IC layout, to ensure that the IC layout satisfies certain manufacturing design rules, i.e., to ensure manufacturability of the IC. If one or more design rules is/are violated, correction is made to at least one of the IC layout or the design by returning the process to operation 110 and/or operation 130. Examples of design rules include, but are not limited to, a width rule which specifies a minimum width of a pattern in the IC layout, a spacing rule which specifies a minimum spacing between adjacent patterns in the IC layout, an area rule which specifies a minimum area of a pattern in the IC layout, a metal-to-via spacing rule which specifies a minimum spacing between a metal pattern and an adjacent via, a metal-to-metal spacing rule, or the like. Other verification processes are usable in some embodiments.

At operation 160, a resistance and capacitance (RC) extraction is performed, e.g., by an EDA tool, to determine parasitic parameters, e.g., parasitic resistance and parasitic capacitance, of interconnects in the IC layout for timing simulations in a subsequent operation. Other verification processes are usable in some embodiments.

At operation 170, a post-layout simulation is performed by a simulation tool, i.e., an EDA tool, to determine, taking the extracted parasitic parameters into account, whether the IC layout meets a predetermined specification. If the simulation indicates that the IC layout does not meet the predetermined specification, e.g., if the parasitic parameters cause undesirable delays, correction is made to at least one of the IC layout or the design by returning the process to operation 110 and/or operation 130. Otherwise, the IC layout is passed to manufacture or additional verification processes.

In some embodiments, one or more evaluations, checks and/or simulations indicate one or more yield and/or performance concerns, and a determination is made to modify the IC layout, e.g., by returning the process to operation 130. An approach for modifying the IC layout is to replace a current layout (or cell) of a circuit in the IC layout with another layout (or another cell) of the same circuit obtained from the at least one library 133. Because multiple layouts of the circuit are available from the at least one library 133, the likelihood of being able to find a better layout than the current layout is increased, which makes it possible to successfully modify the IC layout to address one or more concerns in an efficient manner, in accordance with some embodiments. The modified IC layout is subjected to one or more checks and/or simulations, for example, as described with respect to operations 140-170. When the modified IC layout does not meet one or more requirements at operations 140-170, the process is returned to operation 130 for further layout modifications, with subsequent checks and verifications as described herein. In some embodiments, the IC layout before modification and/or the modified IC layout and/or the final IC layout for manufacture are stored on a non-transitory computer-readable medium.

In some embodiments, one or more of the described operations are omitted. In an example, one or more of the pre-layout simulation in operation 120, the RC extraction in operation 160, and the post-layout simulation in operation 170 is/are omitted, in one or more embodiments. Other arrangements are within the scopes of various embodiments. For simplicity, various operations and/or determinations are described herein as being performed by an APR tool. However, in at least one embodiment, one or more of the described operations and/or determinations are performed outside an APR tool, e.g., by one or more further automated systems, one or more processors, and/or one or more computer systems.

FIG. 2 is a functional flow chart of an IC design flow 200, in accordance with some embodiments. In some embodiments, the IC design flow 200 corresponds to a portion of the design flow 100.

In the IC design flow 200, an IC schematic 210 is provided, or generated, by a circuit designer, e.g., as described with respect to operation 110. In some embodiments, the IC schematic is generated or provided in the form of a schematic netlist as described herein. In the example configuration in FIG. 2, the schematic netlist is provided as a source netlist 220 to be used in an LVS check. In at least one embodiment, the source netlist 220 is a single netlist file which includes descriptions of multiple semiconductor devices at multiple levels of an IC device being designed.

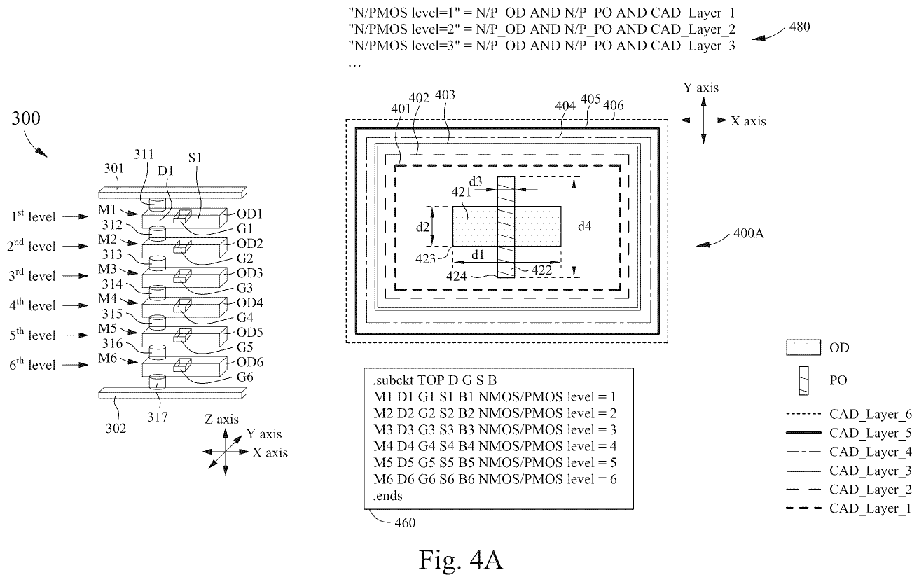

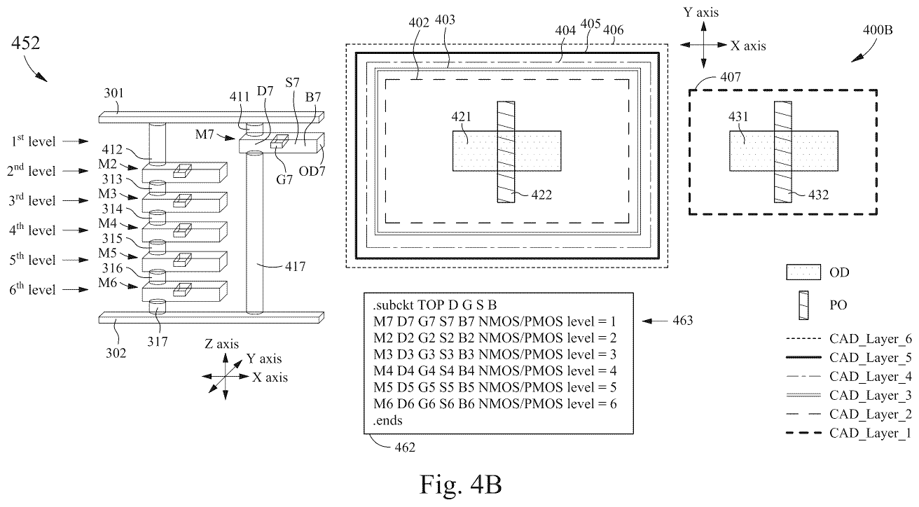

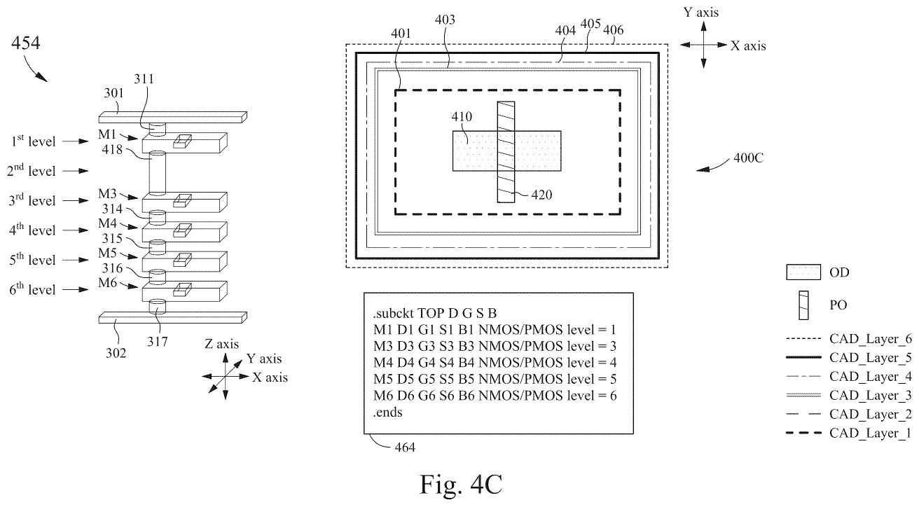

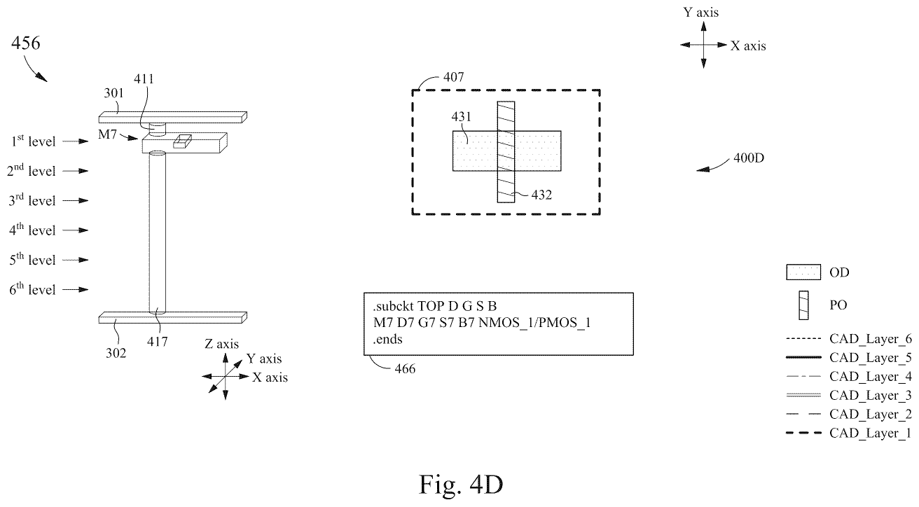

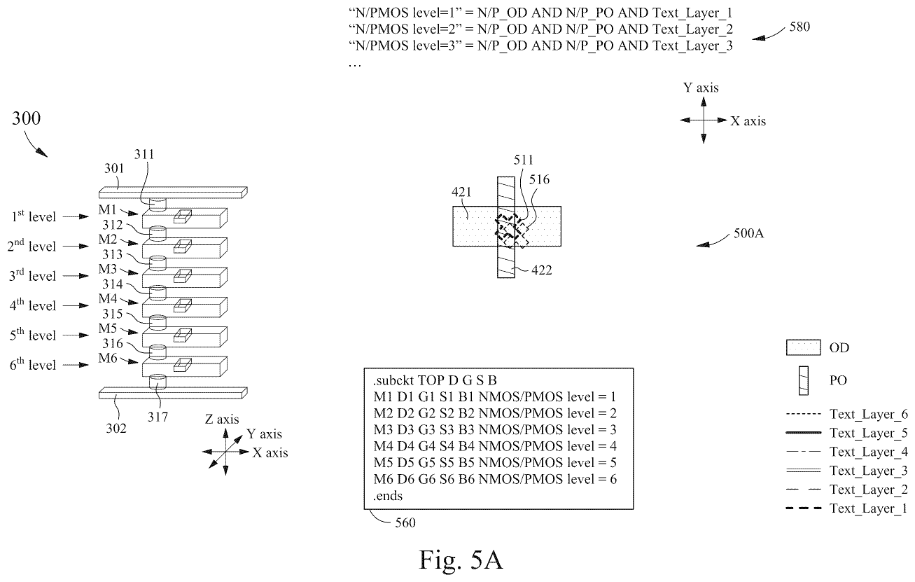

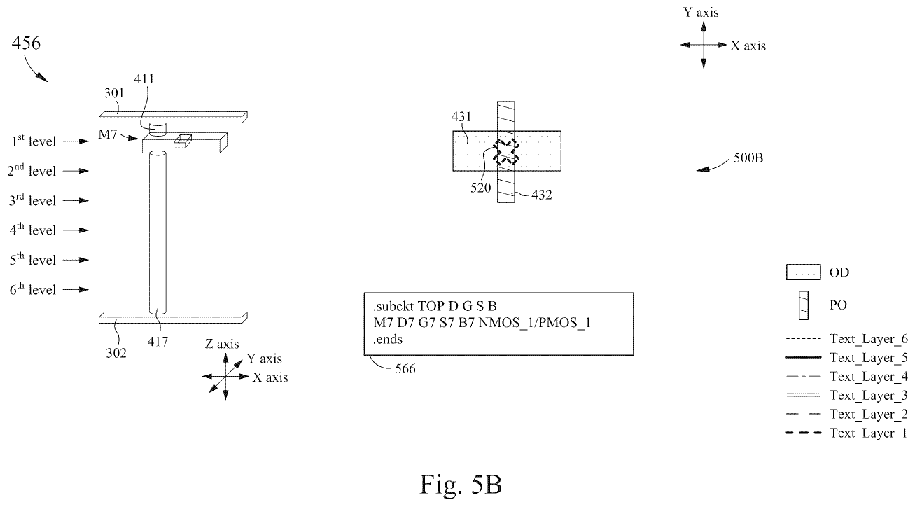

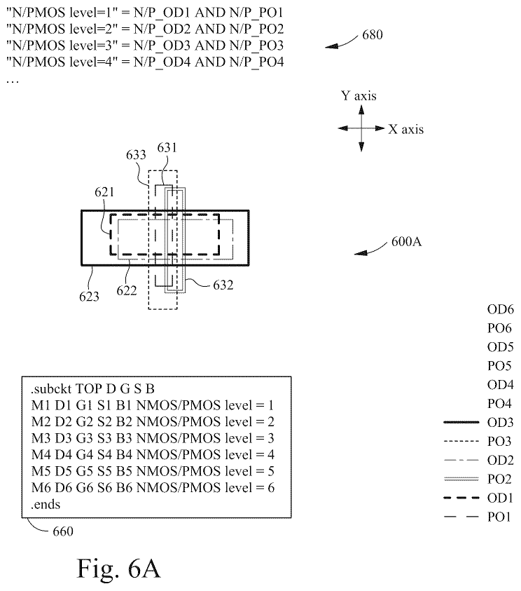

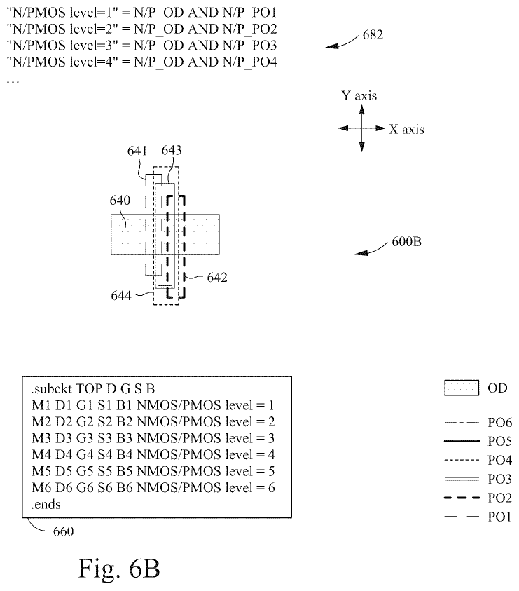

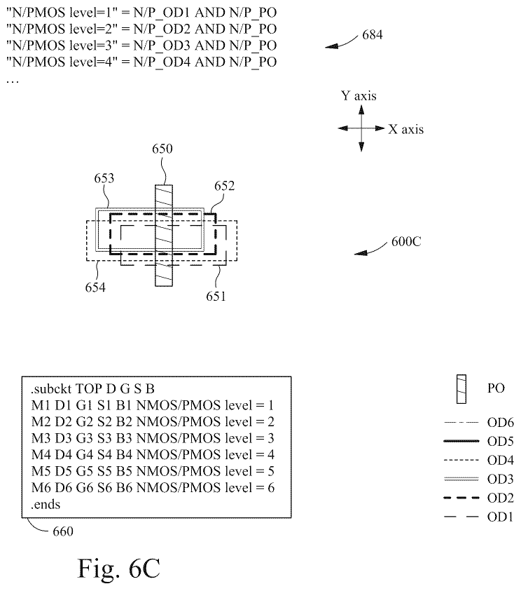

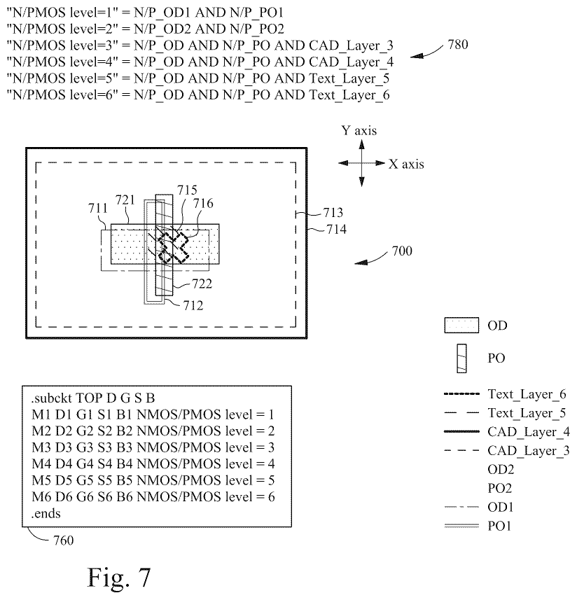

The IC schematic 210 is provided to an APR tool configured to perform an APR operation. As a result of the APR operation, the APR tool is configured to output an IC layout 230 including placed circuit elements (e.g., semiconductor devices) and routing features, e.g., as described with respect to operation 130. In some embodiments, the IC layout 230 further comprises label features indicating levels of semiconductor devices in the IC device. First through fourth layout design methods 231-234 of configuring the IC layout 230 to include such label features are provided in accordance with some embodiments. One or more non-limiting examples of the first layout design method 231 are described with respect to FIGS. 4A-4D. One or more non-limiting examples of the second layout design method 232 are described with respect to FIGS. 5A-5B. One or more non-limiting examples of the third layout design method 233 are described with respect to FIGS. 6A-6C. One or more non-limiting examples of the fourth layout design method 234 are described with respect to FIG. 7.

In at least one embodiment, a decision as to which of the first through fourth layout design methods 231-234 is to be used for including label features indicating levels of semiconductor devices in the IC layout 230 is made based on one or more design requirements. For example, when resource management is a consideration or priority, the first layout design method 231 or the second layout design method 232 is preferred. For another example, when design flexibility is a consideration or priority, the third layout design method 233 or fourth layout design method 234 is preferred. In some embodiments, a human designer (sometimes referred to as MOS owner) makes the decision or selection of which of the first through fourth layout design methods 231-234 is to be used. The IC layout 230 including label features indicating levels of semiconductor devices is output from the APR tool in a GDS file 235. In some embodiments, the GDS file 235 is a single GDS file which includes therein patterns representing various semiconductor devices, as well as label features indicating levels of the semiconductor devices in the IC device being designed. As described herein, other formats, such as GDSII, DFII, OASIS, are usable for an IC layout file including the IC layout 230 output from the APR tool.

The GDS file 235 is provided to an LVS checking tool which also receives the source netlist 220 corresponding to the IC schematic 210, and is configured to perform an LVS check as described with respect to operation 140. In some embodiments, the GDS file 235 is the only IC layout file and the source netlist 220 is the only netlist file needed by the LVS checking tool to perform the LVS check on a plurality of levels of semiconductor devices in the IC device being designed. In some embodiments, the LVS checking tool is configured to recognize, or extract, semiconductor devices as well as connections therebetween from various patterns of the IC layout 230 included in the GDS file 235, and also to generate a layout netlist 240 representing the extracted semiconductor devices and connections. In some embodiments, the LVS checking tool is further configured to determine levels of semiconductor devices based on the label features included in the IC layout 230, and include corresponding label features indicating the levels of the semiconductor devices in the layout netlist 240. The LVS checking tool is configured to compare the source netlist 220 with the layout netlist 240 at an LVS comparison 250. If the layout netlist 240 matches the source netlist 220 within a matching tolerance, i.e., no error is found, the LVS check is passed and the process proceeds to a next stage, e.g., a next verification. However, if the layout netlist 240 does not match the source netlist 220 within the matching tolerance, i.e., the LVS check indicates an error, correction is made to at least one of the IC schematic 210 or IC layout 230 by returning the process to an earlier operation, as described with respect to the design flow 100.

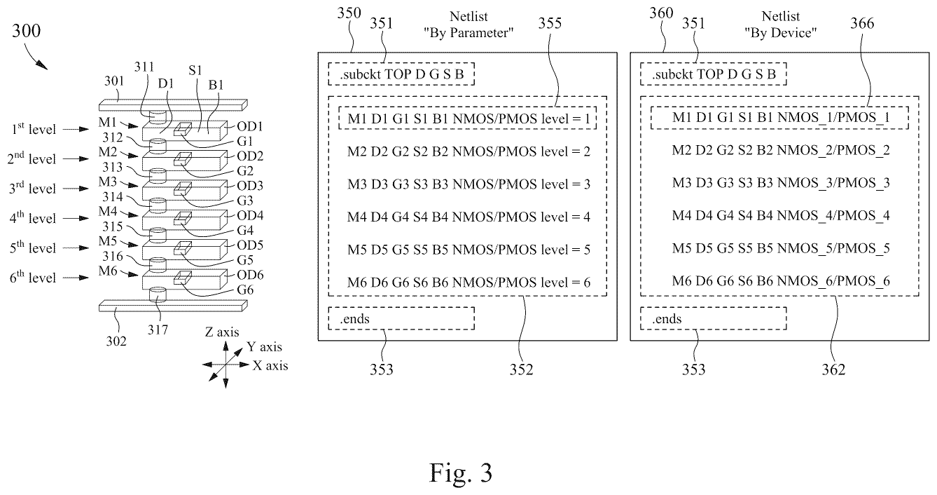

In some embodiments, the levels of the semiconductor devices recognized from label features included in the IC layout 230 are included in the layout netlist 240 in a first netlist format 245 or a second netlist format 246. The first netlist format 245 is also referred to herein as “by parameter”, and the second netlist format 246 is also referred to herein as “by device”. Non-limiting examples of the first netlist format 245 and second netlist format 246 are described with respect to FIG. 3. In some embodiments, the label features included in the IC layout 230 in accordance with any of the first through fourth layout design methods 231-234 are extracted and included in the layout netlist 240 in accordance with any of the first and second netlist formats 245, 246, to indicate the levels of the semiconductor devices. In at least one embodiment, the source netlist 220 has the same format as the layout netlist 240. In an example, both of the source netlist 220 and the layout netlist 240 have the first netlist format 245. In another example, both of the source netlist 220 and the layout netlist 240 have the second netlist format 246.

In at least one embodiment, a decision as to which of the first and second netlist formats 245, 246 is to be used for including label features indicating levels of semiconductor devices in the source netlist 220 and/or the layout netlist 240 is made based on one or more design requirements, and/or complexity of the stacked structure. In some embodiments, a human designer (or MOS owner) makes the decision or selection of which of the first and second netlist formats 245, 246 is to be used for the source netlist 220 and/or the layout netlist 240. One or more advantages described herein, including, but not limited to, accurate and/or efficient LVS check, resource manageability, design flexibility, or the like, are achievable by the IC design flow 200, in accordance with some embodiments.

FIG. 3 includes a schematic perspective view of a circuit region of an IC device 300, and example netlists 350, 360 corresponding to the circuit region, in accordance with some embodiments.

The IC device 300 comprises semiconductor devices arranged at a plurality of levels along a thickness direction, e.g., a Z axis, of the IC device 300. In the example configuration in FIG. 3, the IC device 300 includes six levels, i.e., first to sixth levels, at each of which multiple semiconductor devices are arranged. For simplicity, a representative semiconductor device is depicted at each of the six levels of the IC device 300, whereas other semiconductor devices are omitted. The number of six levels in the IC device 300 is an example. Other numbers of levels of stacked semiconductor devices in an IC device are within the scopes of various embodiments. In some embodiments, an IC device comprises N levels of semiconductor devices and n is an index of a level among the N levels, where N is a natural number greater than 1, and n=1, 2, . . . N. In the example configuration in FIG. 3, N=6, and n=1, 2, . . . 6.

In FIG. 3, the representative semiconductor devices correspondingly at the first to sixth levels include transistors M1-M6. In non-limiting examples described herein in accordance with some embodiments, the transistors M1-M6 comprise n-channel metal-oxide semiconductor (NMOS) and/or p-channel metal-oxide semiconductor (PMOS) transistors. Other types of transistors or other types of semiconductor devices, such as BJTs, varactors, or the like, are within the scopes of various embodiments. For simplicity, in non-limiting examples described herein, the transistors M1-M6 are of the same type, i.e., the transistors M1-M6 are all N-type (e.g., NMOS) transistors, or the transistors M1-M6 are all P-type (e.g., PMOS) transistors.

In some embodiments, the first to sixth levels of semiconductor devices including the transistors M1-M6 are sequentially formed over each other, and over a substrate (not shown), to form a stacked structure. In some embodiments, the substrate is a semiconductor substrate or an isolation substrate.

The transistors M1-M6 comprise corresponding active regions OD1-OD6, and corresponding gates G1-G6. In the stacked structure, along the Z axis, the gate G1 is over the active region OD1, which is over the gate G2, which is over the active region OD2, and so on. At a bottom of the stacked structure, the active region OD5 is over the gate G6 which is over the active region OD6. The active regions OD1-OD6 are elongated along a first direction, e.g., an X axis, and the gates G1-G6 are elongated along a second direction, e.g., an Y axis, transverse to the first direction. The X axis and Y axis are transverse to the Z axis. In at least one embodiment, the X axis, Y axis and Z axis are mutually perpendicular to each other.

Each of the active regions OD1-OD6 includes a source, a drain and a body of the corresponding transistor. For example, the active region OD1 includes a source S1, a drain D1 and a body B1 of the transistor M1. For simplicity, sources, drains and bodies of the other transistors M2-M6 are not specifically indicated in FIG. 3. The active regions OD1-OD6 and the corresponding source/drains therein include semiconductor materials with added N-type and/or P-type dopants to configure each of the corresponding transistors M1-M6 as an N-type (e.g., NMOS) transistor or a P-type (e.g., PMOS) transistor. Example materials of the gates G1-G6 include polysilicon, metal, or the like. Active regions in an IC device and corresponding active region patterns in an IC layout of the IC device are described herein and referred to in the drawings by labels including “OD”. Gates in an IC device and corresponding gate region patterns in an IC layout of the IC device are described herein and referred to in the drawings by labels including “PO”.

The transistors M1-M6 constitute a set of semiconductor devices which overlap each other, at least partially, along the thickness direction, i.e., the Z axis. In some embodiments, a first semiconductor device overlaps, at least partially, a second semiconductor device at a different level when in an X-Y plane (sometimes referred to as “top view”, “plan view” or “layout view”), the gate of the first semiconductor device at least partially overlaps the gate of the second semiconductor device, and/or the active region of the first semiconductor device at least partially overlaps the active region of the second semiconductor device. In the example configuration in FIG. 3, the gates G1-G6 overlap each other at least partially, and the active regions OD1-OD6 overlap each other at least partially. The transistors M1-M6 overlapping each other, at least partially, are sometimes referred to as stacked transistors.

The IC device 300 further comprises contact structures to electrically couple one or more of the transistors M1-M6 with each other and/or with other semiconductor devices in the IC device 300. Example contact structures comprise one or more of source/drain contacts, vias, and metal patterns in one or more metal layers. Source/drain contacts (sometimes referred to as MD contacts) comprise conductive features correspondingly over and in electrical contact with source/drains of transistors. Example vias include, but are not limited to, via-to-gate (VG) vias over and in electrical contact with gates of transistors, via-to-device (VD) vias over and in electrical contact with MD contacts, vias in one or more via layers between metal layers, or the like. In the example configuration in FIG. 3, contact structures 312-316 are illustrated to show electrical connections between source/drains of the transistors M1-M6. A contact structure 311 is over and couples the drain D1 of the transistor M1 to a top metal layer 301 over the stacked structure. A contact structure 317 is under and couples a source/drain of the transistor M6 to a bottom metal layer 302 under the stacked structure. The illustrated contact structures 311-317 are examples. Further contact structures coupled to one or more of the gates G1-G6 and/or the other source/drains of the transistors M1-M6 are within the scopes of various embodiments.

In some embodiments, the IC device 300 further comprises a top redistribution structure (not shown) over the stacked structure. Such a top redistribution structure comprises a plurality of sequentially stacked top metal layers including the top metal layer 301, and top via layers each between a pair of successive top metal layers. Among the top metal layers in the top redistribution structure, the top metal layer 301 is the lowermost metal layer or the closest metal layer to the transistors M1-M6. In some embodiments, the IC device 300 further comprises a bottom redistribution structure (not shown) under the stacked structure. Such a bottom redistribution structure comprises a plurality of sequentially stacked bottom metal layers including the bottom metal layer 302, and bottom via layers each between a pair of successive bottom metal layers. Among the bottom metal layers in the bottom redistribution structure, the bottom metal layer 302 is the uppermost metal layer or the closest metal layer to the transistors M1-M6. The top redistribution structure and/or the bottom redistribution structure are configured to provide electrical connections among various circuits of the IC device 300 and/or to external circuitry for one or more of power, data, control, clock, or the like.

The circuit region of the IC device 300 with the transistors M1-M6 is described in the netlist 350 in accordance with the first netlist format 245, or in the netlist 360 in accordance with the second netlist format 246. In some embodiments, each of the netlists 350, 360 corresponds to any of the source netlist 220 and layout netlist 240.

In the netlist 350, a description of the circuit region including the transistors M1-M6 includes portions 351, 352, 353. The portion 351 including a statement “.subckt” and the portion 353 including a statement “.ends” declare a circuit named “TOP” and corresponding nodes or terminals “D”, “G”, “S”, “B”. The portion 352 further declares that the circuit region includes six transistors M1-M6. Each of the transistors M1-M6 is described in a corresponding line of the portion 352. For example, at a line 355 of the portion 352, the transistor M1 is described as having a name “M1” and terminals “D1”, “G1”, “S1”, “B1” corresponding to the drain D1, gate G1, source S1 and body B1, as described with respect to the IC device 300. The line 355 further specifies a device type of the transistor M1, i.e., whether the transistor M1 is an NMOS transistor or a PMOS transistor. For example, when the transistor M1 is an NMOS transistor, the line 355 reads as follows:

M1 D1 G1 S1 B1 NMOS Level=1

For another example, when the transistor M1 is a PMOS transistor, the line 355 reads as follows:

M1 D1 G1 S1 B1 PMOS Level=1

The line 355 further includes a parameter “level=1” serving as a label feature indicating the level, i.e., the first level, at which the transistor M1 is arranged in the IC device 300. The other transistors M2-M6 are described similarly in corresponding lines of the portion 352, and detailed descriptions of such lines are omitted herein.

The description of each of the transistors M1-M6 in the netlist 350 includes a corresponding parameter, or label feature, “level=n”, where n is the index of the corresponding level among the levels of the IC device 300. In the example configuration in FIG. 3, n=1, 2, . . . 6. In other words, the description of each of the transistors M1-M6 in the netlist 350 includes a label feature indicating the level of the corresponding transistor. In the netlist 350, the descriptions of all transistors or semiconductor devices arranged at a level n of the IC device 300 include the same parameter, or label feature, “level=n”. This parameter or label feature is not included in netlists in accordance with other approaches, and in one or more embodiments makes it possible to achieve accurate and/or efficient verifications, including an LVS check, of the current design of the IC device 300.

In the netlist 360, a description of the circuit region including the transistors M1-M6 includes portions 351, 362, 353. The portions 351, 353 are as described with respect to the netlist 350. The portion 362 is similar to the portion 352 in the description of the name and terminals of each transistor. However, the portion 362 differs from the portion 362 in the description of the device type and level of each transistor. Specifically, at a line 366 of the portion 362 where the transistor M1 is described, the level (first level) of the transistor M1 is included as a part of a device type of the transistor M1. For example, when the transistor M1 is an NMOS transistor at the first level, the line 366 reads as follows:

M1 D1 G1 S1 B1 NMOS_1

For another example, when the transistor M1 is a PMOS transistor at the first level, the line 366 reads as follows:

M1 D1 G1 S1 B1 PMOS_1

The part “1” in the device type “NMOS_1” or “PMOS_1” serves as a label feature indicating the level, i.e., the first level, at which the transistor M1 is arranged in the IC device 300. The other transistors M2-M6 are described similarly in corresponding lines of the portion 362, and detailed descriptions of such lines are omitted herein.

The description of the level of each of the transistors M1-M6 in the netlist 360 is included in the device type “NMOS_n” or “PMOS_n”, where n is the index of the level among the levels of the IC device 300. In the example configuration in FIG. 3, n=1, 2, . . . 6. In the netlist 360, the descriptions of all NMOS transistors arranged at a level n of the IC device 300 include the same device type “NMOS_n”, whereas the descriptions of all PMOS transistors arranged at the level n of the IC device 300 include the same device type “PMOS_n”. In other words, “n” in the device type “NMOS_n” or “PMOS_n” of each transistor serves as a label feature indicating the level of the transistor. This label feature is not included in netlists in accordance with other approaches, and in one or more embodiments makes it possible to achieve accurate and/or efficient verifications, including an LVS check, of the current design of the IC device 300.

FIG. 4A includes the same schematic perspective view of the circuit region of the IC device 300 described with respect to FIG. 3, and an example IC layout 400A and an example netlist 460 corresponding to the circuit region, in accordance with some embodiments. In some embodiments, the IC layout 400A corresponds to the IC layout 230, is generated by an APR tool, and/or is output from the APR tool in the form of the GDS file 235. The IC layout 400A is an example of an IC layout generated in accordance with the first layout design method 231, in one or more embodiments.

As described herein, each transistor of an IC device has a corresponding gate and a corresponding active region. The transistor is represented in an IC layout of the IC device by a gate region pattern corresponding to the gate, and an active region pattern corresponding to the active region. A gate region pattern is defined in the IC layout by a position and a size of the gate region pattern. An active region pattern is defined in the IC layout by a position and a size of the active region pattern. For example, in the IC layout 400A, an active region pattern 421 is defined by its position, which includes coordinates, in the X axis and Y axis, of a corner 423 of the active region pattern 421. The active region pattern 421 is further defined by its size, which includes dimensions d1, d2 correspondingly in the X axis and Y axis. Similarly, in the IC layout 400A, a gate region pattern 422 is defined by its position, which includes coordinates, in the X axis and Y axis, of a corner 424 of the gate region pattern 422. The gate region pattern 422 is further defined by its size, which includes dimensions d3, d4 correspondingly in the X axis and Y axis.

The first layout design method 231 is applicable where multiple stacked transistors at different levels have the same active region pattern and the same gate region pattern in the IC layout. In some embodiments, two stacked transistors have the same active region pattern where the active region pattern of one of the stacked transistors has the same position, size and type (e.g., active region pattern for N-type transistor or for P-type transistor) as the active region pattern of the other transistor. Similarly, two stacked transistors have the same gate region pattern where the gate region pattern of one of the stacked transistors has the same position, size and type (e.g., gate region pattern for N-type transistor or for P-type transistor) as the gate region pattern of the other transistor. In the example configuration in FIG. 4A, all of the transistors M1-M6 have the same active region pattern and the same gate region pattern, and are represented in the IC layout 400A by the active region pattern 421 and the gate region pattern 422 which are correspondingly the common active region pattern and the common gate region pattern of the transistors M1-M6. In some embodiments, the active region pattern 421 belongs to an active region layer OD in a GDS file representing the IC layout 400A, and the gate region pattern 422 belongs to a different, gate region layer PO in the GDS file. In at least one embodiment, at least one of the active region layer OD containing the active region pattern 421 or the gate region layer PO containing the gate region pattern 422 is a computer assisted design (CAD) layer.

The IC layout 400A further comprises label features indicating levels, in the IC device 300, at which the transistors M1-M6 are correspondingly arranged. According to the first layout design method 231, an IC layout of an IC device comprises, for each level of semiconductor devices in the IC device, a corresponding CAD layer containing label features of the semiconductor devices at that level. For example, the IC layout 400A comprises six different CAD layers CAD_Layer_1, CAD_Layer_2 . . . CAD_Layer_6 corresponding to six levels, i.e., the first to sixth levels, of semiconductor devices in the IC device 300. Label features for the transistor M1 as well as other transistors or semiconductor devices at the first level of the IC device 300 are included in CAD_Layer_1, label features for the transistor M2 as well as other transistors or semiconductor devices at the second level of the IC device 300 are included in CAD_Layer_2, or the like.

In the example configuration in FIG. 4A, label features for the transistors M1-M6 include frames 401-406 which extend around the active region pattern 421 and the gate region pattern 422 in the layout view, and are correspondingly included in CAD_Layer_1 to CAD_Layer_6. The shapes and/or sizes of the frames 401-406 serving as label features are examples. Other configurations of label features are within the scopes of various embodiments.

In some embodiments, the CAD_Layer_1 to CAD_Layer_6 are different from the CAD layers correspondingly containing the active region pattern 421 and the gate region pattern 422. As a result, the IC layout 400A generated in accordance with the first layout design method 231 includes eight CAD layers for representing transistors in six levels of the IC device 300. This arrangement, in one or more embodiments, is an efficient resource management, i.e., CAD layers in the GDS file are efficiently utilized to represent transistors and their corresponding levels.

The GDS file including the IC layout 400A is provided to an LVS checking tool which is configured to extract, from the GDS file, transistors, connections and levels of the transistors, to generate a layout netlist, as described with respect to FIG. 2. The netlist 460 in FIG. 4A is an example layout netlist generated by the LVS checking tool from the GDS file including the IC layout 400A. The netlist 460 corresponding to the IC layout 400A is generated in accordance with the first netlist format 245, and is the same as the netlist 350. In some embodiments, a layout netlist (not shown in FIG. 4A) corresponding to the IC layout 400A is generated in accordance with the second netlist format 246, and is the same as the netlist 360.

To generate the netlist 460 in accordance with the first netlist format 245, the LVS checking tool is configured to use a first set of settings 480. For example, a setting in the first set of settings 480 for the first level of the IC device 300 and the corresponding CAD_Layer_1 of the IC layout 400A reads as follows:

“N/PMOS level=1”=N/P_OD AND N/P_PO AND CAD_Layer_1

This setting means that when the LVS checking tool extracts a transistor (e.g., transistor M1) having an active region pattern for N-type transistor (i.e., “N_OD”), a gate region pattern for N-type transistor (i.e., “N_PO”), and a label feature (e.g., the frame 401) in CAD_Layer_1 at a location corresponding to (e.g., surrounding) the extracted active region pattern and gate region pattern, the LVS checking tool adds “NMOS level=1” to the description of the transistor M1 in the netlist 460. When the LVS checking tool extracts transistor M1 having an active region pattern for P-type transistor (i.e., “P_OD”), a gate region pattern for P-type transistor (i.e., “P_PO”), and a label feature (e.g., the frame 401) in CAD_Layer_1, the LVS checking tool adds “PMOS level=1” to the description of the transistor M1 in the netlist 460. Other settings in the first set of settings 480 are similarly used by the LVS checking tool to extract transistors and their levels, and add corresponding descriptions and label features to the netlist 460.

To generate a layout netlist (same as the netlist 360) in accordance with the second netlist format 246, the LVS checking tool is configured to use a second set of settings (not shown). For example, a setting in the second set of settings for the first level of the IC device 300 and the corresponding CAD_Layer_1 of the IC layout 400A reads as follows:

“NMOS_1/PMOS_1”=N/P_OD AND N/P_PO AND CAD_Layer_1

This setting means that when the LVS checking tool extracts a transistor (e.g., transistor M1) having an active region pattern for N-type transistor (i.e., “N_OD”), a gate region pattern for N-type transistor (i.e., “N_PO”), and a label feature (e.g., the frame 401) in CAD_Layer_1 at a location corresponding to (e.g., surrounding) the extracted active region pattern and gate region pattern, the LVS checking tool adds “NMOS_1” to the description of the transistor M1 in the layout netlist. When the LVS checking tool extracts transistor M1 having an active region pattern for P-type transistor (i.e., “P_OD”), a gate region pattern for P-type transistor (i.e., “P_PO”), and a label feature (e.g., the frame 401) in CAD_Layer_1, the LVS checking tool adds “PMOS_1” to the description of the transistor M1 in the layout netlist. Other settings in the second set of settings are similarly configured and used by the LVS checking tool to extract transistors and their levels, and add corresponding descriptions and label features to the layout netlist in accordance with the second netlist format 246.

FIG. 4B includes a schematic perspective view of a circuit region of an IC device 452, and an example IC layout 400B and an example netlist 462 corresponding to the circuit region, in accordance with some embodiments. Components in FIG. 4B having corresponding components in one or more of the other figures are designated by the same reference numerals as in the other figures. In some embodiments, the IC layout 400B corresponds to the IC layout 230, is generated by an APR tool, and/or is output from the APR tool in the form of the GDS file 235. The IC layout 400B is a further example of an IC layout generated in accordance with the first layout design method 231, in one or more embodiments.

The IC device 452 is similar to the IC device 300, but differs from the IC device 300 in that the transistor M1 and the contact structures 311, 312 are omitted, whereas a transistor M7 and contact structures 411, 412, 417 are included. The transistor M7 is at the first level, and does not overlap the transistors M2-M6. The transistor M7 comprises a gate G7 and an active region OD7 having a source S7, a drain D7 and a body B7. The contact structure 421 couples the transistor M2 to the top metal layer 301, and the contact structures 411, 417 correspondingly couple the transistor M7 to the top metal layer 301 and bottom metal layer 302.

In the IC layout 400B corresponding to the circuit region of the IC device 452, the transistors M2-M6 are commonly represented by the active region pattern 421 and gate region pattern 422, and are correspondingly represented by label features (e.g., the frames 402-406) in CAD_Layer_2 to CAD_Layer_6, as described with respect to FIG. 4A. However, in CAD_Layer_1, the frame 401 around the active region pattern 421 and gate region pattern 422 is omitted. Instead, the CAD_Layer_1 includes a frame 407 extending around an active region pattern 431 and a gate region pattern 432 which represent the transistor M7. The frame 407 in CAD_Layer_1 serves as a label feature indicating the level (i.e., the first level) of the transistor M7 in the IC device 452.

In some embodiments, using the first set of settings 480 described with respect to FIG. 4A, the netlist 462 corresponding to the circuit region of the IC device 452 is generated by an LVS checking tool in accordance with the first netlist format 245. The netlist 462 is similar to the netlist 460 or the netlist 350, except that the description of the transistor M1 is omitted, and replaced by a description of the transistor M7, at line 463 of the netlist 462.

In at least one embodiment, using the second set of settings described with respect to FIG. 4A, a layout netlist (not shown) corresponding to the circuit region of the IC device 452 is generated by an LVS checking tool in accordance with the second netlist format 246. Such a layout netlist is similar to the netlist 360, except that the description of the transistor M1 is omitted, and replaced by a description of the transistor M7, as follows:
M7 D7 G7 S7 B7 NMOS_1, where the transistor M7 is an NMOS transistor, or
M7 D7 G7 S7 B7 PMOS_1, where the transistor M7 is a PMOS transistor.

FIG. 4C includes a schematic perspective view of a circuit region of an IC device 454, and an example IC layout 400C and an example netlist 464 corresponding to the circuit region, in accordance with some embodiments. Components in FIG. 4C having corresponding components in one or more of the other figures are designated by the same reference numerals as in the other figures. In some embodiments, the IC layout 400C corresponds to the IC layout 230, is generated by an APR tool, and/or is output from the APR tool in the form of the GDS file 235. The IC layout 400C is a further example of an IC layout generated in accordance with the first layout design method 231, in one or more embodiments.

The IC device 454 is similar to the IC device 300, but differs from the IC device 300 in that the transistor M2 and the contact structures 312, 313 are omitted, whereas a contact structure 418 is included. The set of stacked transistors M1 and M3-M6 lacks a transistor at the second level. The contact structure 418 couple the transistors M1, M3 with each other.

In the IC layout 400C corresponding to the circuit region of the IC device 454, the transistors M1 and M3-M6 are commonly represented by the active region pattern 421 and gate region pattern 422, and have corresponding label features in the form of the frames 401 and 403-406, as described with respect to FIG. 4A. However, the frame 402 in CAD_Layer_2 is omitted for the active region pattern 421 and gate region pattern 422.

In some embodiments, using the first set of settings 480 described with respect to FIG. 4A, the netlist 464 corresponding to the circuit region of the IC device 454 is generated by an LVS checking tool in accordance with the first netlist format 245. The netlist 464 is similar to the netlist 460 or the netlist 350, except that the description of the transistor M2 is omitted.

In at least one embodiment, using the second set of settings described with respect to FIG. 4A, a layout netlist (not shown) corresponding to the circuit region of the IC device 454 is generated by an LVS checking tool in accordance with the second netlist format 246. Such a layout netlist is similar to the netlist 360, except that the description of the transistor M2 is omitted.

FIG. 4D includes a schematic perspective view of a circuit region of an IC device 456, and an example IC layout 400D and an example netlist 466 corresponding to the circuit region, in accordance with some embodiments. Components in FIG. 4D having corresponding components in one or more of the other figures are designated by the same reference numerals as in the other figures. In some embodiments, the IC layout 400D corresponds to the IC layout 230, is generated by an APR tool, and/or is output from the APR tool in the form of the GDS file 235. The IC layout 400D is a further example of an IC layout generated in accordance with the first layout design method 231, in one or more embodiments.

The IC device 456 is similar to the IC device 452, but differs from the IC device 452 in that the transistors M2-M6 and the corresponding contact structures are omitted.

In the IC layout 400D corresponding to the circuit region of the IC device 456, the frame 407 is included in CAD_Layer_1, extends around the active region pattern 431 and gate region pattern 432 representing the transistor M7, and serves as a label feature indicating the level (i.e., the first level) of the transistor M7 in the IC device 456.

In some embodiments, using the first set of settings 480 described with respect to FIG. 4A, a layout netlist (not shown) corresponding to the circuit region of the IC device 456 is generated by an LVS checking tool in accordance with the first netlist format 245. Such a layout netlist is similar to the netlist 462, except that the descriptions of the transistors M2-M6 are omitted.

In at least one embodiment, using the second set of settings described with respect to FIG. 4A, the netlist 466 corresponding to the circuit region of the IC device 456 is generated by an LVS checking tool in accordance with the second netlist format 246. The layout netlist 466 includes a device type for the transistor M7 as “NMOS_1” where the transistor M7 is an NMOS transistor, or as “PMOS_1” where the transistor M7 is a PMOS transistor. In some embodiments, one or more advantages described herein are achievable by IC layouts, e.g., the IC layouts 400A-400D, generated in accordance with the first layout design method 231, and/or by layout netlists corresponding to such IC layouts and generated in accordance with the first netlist format 245 or the second netlist format 246.

FIG. 5A includes the same schematic perspective view of the circuit region of the IC device 300 described with respect to FIG. 3, and an example IC layout 500A and an example netlist 560 corresponding to the circuit region, in accordance with some embodiments. Components in FIG. 5A having corresponding components in one or more of the other figures are designated by the same reference numerals as in the other figures. In some embodiments, the IC layout 500A corresponds to the IC layout 230, is generated by an APR tool, and/or is output from the APR tool in the form of the GDS file 235. The IC layout 500A is an example of an IC layout generated in accordance with the second layout design method 232, in one or more embodiments.

Like the first layout design method 231, the second layout design method 232 is applicable where multiple stacked transistors at different levels have the same active region pattern and the same gate region pattern in the IC layout. In the example configuration in FIG. 5A, all of the transistors M1-M6 have the same active region pattern and the same gate region pattern, and are commonly represented in the IC layout 500A by the active region pattern 421 and the gate region pattern 422, as described with respect to FIG. 4A.

The IC layout 500A further comprises label features indicating levels, in the IC device 300, at which the transistors M1-M6 are correspondingly arranged. According to the second layout design method 232, an IC layout of an IC device comprises, for each level of semiconductor devices in the IC device, a corresponding text layer containing label features of the semiconductor devices at that level. For example, the IC layout 500A comprises six different text layers Text_Layer_1, Text_Layer_2 . . . Text_Layer_6 corresponding to six levels, i.e., the first to sixth levels, of semiconductor devices in the IC device 300. Label features for the transistor M1 as well as other transistors or semiconductor devices at the first level of the IC device 300 are included in Text_Layer_1, label features for the transistor M2 as well as other transistors or semiconductor devices at the second level of the IC device 300 are included in Text_Layer_2, or the like.

In the example configuration in FIG. 5A, label features for the transistors M1-M6 include text labels which overlap the active region pattern 421 and the gate region pattern 422 in the layout view, and are correspondingly included in Text_Layer_1 to Text_Layer_6. For example, the label feature for the transistor M1 includes a text label, e.g., “level1”, which is included in Text_Layer_1, and is arranged at a location marked by an X-shaped symbol 511. For another example, the label feature for the transistor M6 includes a text label, e.g., “level6”, which is included in Text_Layer_6, and is arranged at a location marked by an X-shaped symbol 516. In some embodiments, the X-shaped symbols 511, 516 are not actually included in the IC layout 500A. Rather, they are provided herein for illustration purposes to show example locations where the corresponding text labels “level1”, “level6” are arranged in the IC layout 500A. Similar text labels, e.g., “level2” “level5”, correspondingly in Text_Layer_2 to Text_Layer_5, are also included in the IC layout 500A as corresponding label features for the transistors M2-M5. Example locations where the text labels “level2” “level5” are arranged in the IC layout 500A are not illustrated in FIG. 5A, for simplicity. In some embodiments, some or all of the text labels “level1” “level6” are arranged at the same location, e.g., the X-shaped symbol 511 is at the same location as the X-shaped symbol 516. The described particular text labels “level1” “level6” serving as label features are examples. Other configurations of label features are within the scopes of various embodiments.

The GDS file including the IC layout 500A is provided to an LVS checking tool which is configured to extract, from the GDS file, transistors, connections and levels of the transistors, to generate a layout netlist, as described with respect to FIG. 2. The netlist 560 in FIG. 5A is an example layout netlist generated by the LVS checking tool from the GDS file including the IC layout 500A. The netlist 560 corresponding to the IC layout 500A is generated in accordance with the first netlist format 245, and is the same as the netlist 350. In some embodiments, a layout netlist (not shown in FIG. 5A) corresponding to the IC layout 500A is generated in accordance with the second netlist format 246, and is the same as the netlist 360.

To generate the netlist 560 in accordance with the first netlist format 245, the LVS checking tool is configured to use a first set of settings 580. For example, a setting in the first set of settings 580 for the first level of the IC device 300 and the corresponding Text_Layer_1 of the IC layout 500A reads as follows:

“N/PMOS level=1”=N/P_OD AND N/P_PO AND Text_Layer_1

This setting means that when the LVS checking tool extracts a transistor (e.g., transistor M1) having an active region pattern for N-type transistor (i.e., “N_OD”), a gate region pattern for N-type transistor (i.e., “N_PO”), and a label feature (e.g., the text label “level1” described with respect to the X-shaped symbol 511) in Text_Layer_1 at a location corresponding to (e.g., overlapping) the extracted active region pattern and gate region pattern, the LVS checking tool adds “NMOS level=1” to the description of the transistor M1 in the netlist 560. When the LVS checking tool extracts transistor M1 having an active region pattern for P-type transistor (i.e., “P_OD”), a gate region pattern for P-type transistor (i.e., “P_PO”), and a label feature (e.g., the text label “level1”) in Text_Layer_1, the LVS checking tool adds “PMOS level=1” to the description of the transistor M1 in the netlist 560. Other settings in the first set of settings 580 are similarly used by the LVS checking tool to extract transistors and their levels, and add corresponding descriptions and label features to the netlist 560.

To generate a layout netlist (same as the netlist 360) in accordance with the second netlist format 246, the LVS checking tool is configured to use a second set of settings (not shown). For example, a setting in the second set of settings for the first level of the IC device 300 and the corresponding Text_Layer_1 of the IC layout 500A reads as follows:

“NMOS_1/PMOS_1”=N/P_OD AND N/P_PO AND Text_Layer_1

This setting means that when the LVS checking tool extracts a transistor (e.g., transistor M1) having an active region pattern for N-type transistor (i.e., “N_OD”), a gate region pattern for N-type transistor (i.e., “N_PO”), and a label feature (e.g., the text label “level1” described with respect to the X-shaped symbol 511) in Text_Layer_1 at a location corresponding to (e.g., overlapping) the extracted active region pattern and gate region pattern, the LVS checking tool adds “NMOS_1” to the description of the transistor M1 in the layout netlist. When the LVS checking tool extracts transistor M1 having an active region pattern for P-type transistor (i.e., “P_OD”), a gate region pattern for P-type transistor (i.e., “P_PO”), and a label feature (e.g., the text label “level1”) in Text_Layer_1, the LVS checking tool adds “PMOS_1” to the description of the transistor M1 in the layout netlist. Other settings in the second set of settings are similarly configured and used by the LVS checking tool to extract transistors and their levels, and add corresponding descriptions and label features to the layout netlist in accordance with the second netlist format 246.

In some embodiments, IC layouts generated in accordance with the first layout design method 231 using CAD layers for indicating levels of semiconductor devices provide high precision, although a thorough understanding of the purpose and function of each CAD layer is a potential consideration when the first layout design method 231 is used. In contrast, in at least one embodiment, IC layouts generated in accordance with the second layout design method 232 using text layers for indicating levels of semiconductor devices are easy to use in a relatively straightforward manner, although intuitive visualization capabilities are potential considerations when the second layout design method 232 is used.

FIG. 5B includes the same schematic perspective view of the circuit region of the IC device 456 described with respect to FIG. 4D, and an example IC layout 500B and an example netlist 566 corresponding to the circuit region, in accordance with some embodiments. Components in FIG. 5B having corresponding components in one or more of the other figures are designated by the same reference numerals as in the other figures. In some embodiments, the IC layout 500B corresponds to the IC layout 230, is generated by an APR tool, and/or is output from the APR tool in the form of the GDS file 235. The IC layout 500B is a further example of an IC layout generated in accordance with the second layout design method 232, in one or more embodiments.

In the IC layout 500B corresponding to the circuit region of the IC device 456, a label feature for the transistor M7 includes a text label, e.g., “level1”, which is included in Text_Layer_1, and is arranged at a location marked by an X-shaped symbol 520, in a manner similar to that described with respect to the transistor M1 and the corresponding label feature at the X-shaped symbol 511 in FIG. 5A.

In some embodiments, using the first set of settings 580 described with respect to FIG. 5A, a layout netlist (not shown) corresponding to the circuit region of the IC device 456 is generated by an LVS checking tool in accordance with the first netlist format 245. Such a layout netlist is similar to the netlist 462, except that the descriptions of the transistors M2-M6 are omitted.

In at least one embodiment, using the second set of settings described with respect to FIG. 5A, the netlist 566 corresponding to the circuit region of the IC device 456 is generated by an LVS checking tool in accordance with the second netlist format 246. The layout netlist 566 includes a device type for the transistor M7 as “NMOS_1” where the transistor M7 is an NMOS transistor, or as “PMOS_1” where the transistor M7 is a PMOS transistor. The netlist 566 is the same as the netlist 466. In some embodiments, one or more advantages described herein are achievable by IC layouts, e.g., the IC layouts 500A-500B, generated in accordance with the second layout design method 232, and/or by layout netlists corresponding to such IC layouts and generated in accordance with the first netlist format 245 or the second netlist format 246.

FIG. 6A includes an example IC layout 600A and an example netlist 660 corresponding to the circuit region of the IC device 300 described with respect to FIG. 3, in accordance with some embodiments. Components in FIG. 6A having corresponding components in one or more of the other figures are designated by the same reference numerals as in the other figures. In some embodiments, the IC layout 600A corresponds to the IC layout 230, is generated by an APR tool, and/or is output from the APR tool in the form of the GDS file 235. The IC layout 600A is an example of an IC layout generated in accordance with the third layout design method 233, in one or more embodiments.

Like the first layout design method 231 and the second layout design method 232, the third layout design method 233 is applicable where multiple stacked transistors at different levels have the same active region pattern and the same gate region pattern in an IC layout. The third layout design method 233 is further applicable even where multiple stacked transistors at different levels have different active region patterns and/or different gate region patterns. In other words, the third layout design method 233 has broader applicability than the first layout design method 231 and the second layout design method 232, in one or more embodiments.

In FIG. 6A, the IC layout 600A is generated in accordance with the third layout design method 233 for a situation where multiple stacked transistors at different levels have different active region patterns and different gate region patterns. For example, all of the transistors M1-M6 have different active region patterns and different gate region patterns, and each of the transistor M6 is represented in the IC layout 600A by a corresponding active region pattern and a corresponding gate region pattern. Specifically, the transistor M1 is represented by an active region pattern 621 in an active region layer OD1 and a gate region pattern 631 in a gate region layer PO1, the transistor M2 is represented by an active region pattern 622 in an active region layer OD2 and a gate region pattern 632 in a gate region layer PO2, the transistor M3 is represented by an active region pattern 623 in an active region layer OD3 and a gate region pattern 633 in a gate region layer PO3, or the like. Active region patterns and gate region patterns of the transistors M4-M6 are not shown in FIG. 6A for simplicity, and are correspondingly included in active region layers OD4 to OD6, and in gate region layers PO4 to PO6. The illustration in FIG. 6A that the active region patterns 621-623 differ from each other in both position and size is an example. In some embodiments, some of the active region patterns of the transistors M1-M6 differ in position but have the same size and/or some of the active region patterns of the transistors M1-M6 differ in size but have the same position. Similarly, in one or more embodiments, some of the gate region patterns of the transistors M1-M6 differ in position but have the same size and/or some of the gate region patterns of the transistors M1-M6 differ in size but have the same position.

The active region layer OD1 and the gate region layer PO1 correspondingly include active region patterns and gate region patterns of transistors or semiconductor devices at the first level. As a result, when a transistor extracted from the IC layout 600A by an LVS checking tool has an active region pattern in the active region layer OD1 and a gate region pattern in the gate region layer PO1, the LVS checking tool determines that the extracted transistor belongs to the first level, and includes a corresponding label feature in a layout netlist in accordance with the first netlist format 245 or the second netlist format 246. In other words, the presence of the active region pattern and the gate region pattern of a transistor correspondingly in the active region layer OD1 and the gate region layer PO1 serves as a label feature included in the IC layout 600A to indicate the corresponding level, e.g., the first level, of the transistor. The above description is applicable to the other second to sixth levels and the corresponding active region layers OD2 to OD6 and gate region layers PO2 to PO6. In some embodiments, at least one, or each, of the active region layers OD1 to OD6 and gate region layers PO1 to PO6 is a CAD layer.

The GDS file including the IC layout 600A is provided to an LVS checking tool which is configured to extract, from the GDS file, transistors, connections and levels of the transistors, to generate a layout netlist, as described with respect to FIG. 2. The netlist 660 in FIG. 6A is an example layout netlist generated by the LVS checking tool from the GDS file including the IC layout 600A. The netlist 660 corresponding to the IC layout 600A is generated in accordance with the first netlist format 245, and is the same as the netlist 350. In some embodiments, a layout netlist (not shown in FIG. 6A) corresponding to the IC layout 600A is generated in accordance with the second netlist format 246, and is the same as the netlist 360.

To generate the netlist 660 in accordance with the first netlist format 245, the LVS checking tool is configured to use a first set of settings 680. For example, a setting in the first set of settings 680 for the first level of the IC device 300 and the corresponding active region layer OD1 and gate region layer PO1 of the IC layout 600A reads as follows:

“N/PMOS level=1”=N/P_OD1 AND N/P_PO1

This setting means that when the LVS checking tool extracts a transistor (e.g., transistor M1) having an active region pattern for N-type transistor in the active region layer OD1 and a gate region pattern for N-type transistor in the gate region layer PO1, the LVS checking tool determines that the extracted transistor is an N-type transistor at the first level and adds “NMOS level=1” to the description of the transistor M1 in the netlist 660. When the LVS checking tool extracts transistor M1 having an active region pattern for P-type transistor in the active region layer OD1 and a gate region pattern for P-type transistor in the gate region layer PO1, the LVS checking tool determines that the extracted transistor is a P-type transistor at the first level and adds “PMOS level=1” to the description of the transistor M1 in the netlist 660. Other settings in the first set of settings 680 are similarly used by the LVS checking tool to extract transistors and their levels, and add corresponding descriptions and label features to the netlist 660.

To generate a layout netlist (same as the netlist 360) in accordance with the second netlist format 246, the LVS checking tool is configured to use a second set of settings (not shown). For example, a setting in the second set of settings for the first level of the IC device 300 and the corresponding active region layer OD1 and gate region layer PO1 of the IC layout 600A reads as follows:

“NMOS_1/PMOS_1”=N/P_OD1 AND N/P_PO1

This setting is used by the LVS checking tool in a manner similar to the corresponding setting in the first set of settings 680, except that instead of adding “NMOS level=1” or “PMOS level=1” to the description of the transistor M1 in the layout netlist, the LVS checking tool correspondingly adds “NMOS_1” or “PMOS_1”. Other settings in the second set of settings are similarly configured and used by the LVS checking tool to extract transistors and their levels, and add corresponding descriptions and label features to the layout netlist in accordance with the second netlist format 246.

In the described example(s), the third layout design method 233 uses a greater numbers of layers, e.g., twelve CAD layers, to represent the transistors M1-M6, than the first layout design method 231, which uses eight CAD layers, and the second layout design method 232, which uses two CAD layers plus six text layers, to represent the same set of transistors M1-M6. In at least one embodiment, the first layout design method 231 and/or the second layout design method 232 provide(s) an efficient approach for resource management (in terms of layers or CAD layers used in an IC layout), compared to the third layout design method 233. In some embodiments, however, the third layout design method 233 provides a more flexible approach than the first layout design method 231 and second layout design method 232, because the third layout design method 233 is applicable even where multiple stacked transistors at different levels have different active region patterns and/or different gate region patterns. In some embodiments, IC designers are provided with a variety of approaches with corresponding advantages through the first layout design method 231, the second layout design method 232 and/or the third layout design method 233, which advantageously enhances design flexibility.

FIG. 6B includes an example IC layout 600B and the example netlist 660 corresponding to the circuit region of the IC device 300 described with respect to FIG. 3, in accordance with some embodiments. Components in FIG. 6B having corresponding components in one or more of the other figures are designated by the same reference numerals as in the other figures. In some embodiments, the IC layout 600B corresponds to the IC layout 230, is generated by an APR tool, and/or is output from the APR tool in the form of the GDS file 235. The IC layout 600B is a further example of an IC layout generated in accordance with the third layout design method 233, in one or more embodiments.

In FIG. 6B, the IC layout 600B is generated in accordance with the third layout design method 233 for a situation where multiple stacked transistors at different levels have the same active region pattern and different gate region patterns. For example, all of the transistors M1-M6 have the same or common active region pattern 640 in the active region layer OD, and different gate region patterns correspondingly in the gate region layers PO1-PO6. Specifically, the transistor M1 is represented by the active region pattern 640 and a gate region pattern 641 in the gate region layer PO1, the transistor M2 is represented by the active region pattern 640 and a gate region pattern 642 in the gate region layer PO2, the transistor M3 is represented by the active region pattern 640 and a gate region pattern 643 in the gate region layer PO3, the transistor M4 is represented by the active region pattern 640 and a gate region pattern 644 in the gate region layer PO4, or the like. The gate region patterns of the transistors M5, M6 are not shown in FIG. 6B for simplicity, and are correspondingly included in the gate region layers PO5, PO6. The illustration in FIG. 6B that the gate region patterns 641-644 differ from each other in both position and size is an example. In some embodiments, some of the gate region patterns of the transistors M1-M6 differ in position but have the same size and/or some of the gate region patterns of the transistors M1-M6 differ in size but have the same position.

The gate region layers PO1 to PO6 in the IC layout 600B correspond to the first to sixth levels of the IC device 300. The presence of the gate region pattern of a transistor in the gate region layer PO1 serves as a label feature included in the IC layout 600B to indicate the corresponding level, e.g., the first level, of the transistor. The above description is applicable to the other second to sixth levels and the corresponding gate region layers PO2 to PO6. In some embodiments, at least one, or each, of the active region layer OD and gate region layers PO1 to PO6 is a CAD layer.

To generate the netlist 660 in accordance with the first netlist format 245, the LVS checking tool is configured to use a first set of settings 682. For example, a setting in the first set of settings 682 for the first level of the IC device 300 and the corresponding gate region layer PO1 of the IC layout 600B reads as follows:

“N/PMOS Level=1”=N/P_OD and N/P_PO1

This setting means that when the LVS checking tool extracts a transistor (e.g., transistor M1) having an active region pattern for N-type transistor in the active region layer OD and a gate region pattern for N-type transistor in the gate region layer PO1, the LVS checking tool determines that the extracted transistor is an N-type transistor at the first level and adds “NMOS level=1” to the description of the transistor M1 in the netlist 660. When the LVS checking tool extracts transistor M1 having an active region pattern for P-type transistor in the active region layer OD and a gate region pattern for P-type transistor in the gate region layer PO1, the LVS checking tool determines that the extracted transistor is a P-type transistor at the first level and adds “PMOS level=1” to the description of the transistor M1 in the netlist 660. Other settings in the first set of settings 682 are similarly used by the LVS checking tool to extract transistors and their levels, and add corresponding descriptions and label features to the netlist 660.

To generate a layout netlist (same as the netlist 360) in accordance with the second netlist format 246, the LVS checking tool is configured to use a second set of settings (not shown). For example, a setting in the second set of settings for the first level of the IC device 300 and the corresponding gate region layer PO1 of the IC layout 600B reads as follows:

“NMOS_1/PMOS_1”=N/P_OD AND N/P_PO1

This setting is used by the LVS checking tool in a manner similar to the corresponding setting in the first set of settings 682, except that instead of adding “NMOS level=1” or “PMOS level=1” to the description of the transistor M1 in the layout netlist, the LVS checking tool correspondingly adds “NMOS_1” or “PMOS_1”. Other settings in the second set of settings are similarly configured and used by the LVS checking tool to extract transistors and their levels, and add corresponding descriptions and label features to the layout netlist in accordance with the second netlist format 246.

FIG. 6C includes an example IC layout 600C and the example netlist 660 corresponding to the circuit region of the IC device 300 described with respect to FIG. 3, in accordance with some embodiments. Components in FIG. 6C having corresponding components in one or more of the other figures are designated by the same reference numerals as in the other figures. In some embodiments, the IC layout 600C corresponds to the IC layout 230, is generated by an APR tool, and/or is output from the APR tool in the form of the GDS file 235. The IC layout 600C is a further example of an IC layout generated in accordance with the third layout design method 233, in one or more embodiments.

In FIG. 6C, the IC layout 600C is generated in accordance with the third layout design method 233 for a situation where multiple stacked transistors at different levels have the same gate region pattern and different active region patterns. For example, all of the transistors M1-M6 have the same or common gate region pattern 650 in the gate region layer PO, and different active region patterns correspondingly in the active region layers OD1-OD6. Specifically, the transistor M1 is represented by the gate region pattern 650 and an active region pattern 651 in the active region layer OD1, the transistor M2 is represented by the gate region pattern 650 and an active region pattern 652 in the active region layer OD2, the transistor M3 is represented by the gate region pattern 650 and an active region pattern 653 in the active region layer OD3, the transistor M4 is represented by the gate region pattern 650 and an active region pattern 654 in the active region layer OD4, or the like. The active region patterns of the transistors M5-M6 are not shown in FIG. 6C for simplicity, and are correspondingly included in the active region layers OD5, OD6. The illustration in FIG. 6C that the active region patterns 651-654 differ from each other in both position and size is an example. In some embodiments, some of the active region patterns of the transistors M1-M6 differ in position but have the same size and/or some of the active region patterns of the transistors M1-M6 differ in size but have the same position.

The active region layers OD1 to OD6 in the IC layout 600C correspond to the first to sixth levels of the IC device 300. The presence of the active region pattern of a transistor in the active region layer OD1 serves as a label feature included in the IC layout 600C to indicate the corresponding level, e.g., the first level, of the transistor. The above description is applicable to the other second to sixth levels and the corresponding active region layers OD2 to OD6. In some embodiments, at least one, or each, of the gate region layer PO and active region layers OD1 to OD6 is a CAD layer.

To generate the netlist 660 in accordance with the first netlist format 245, the LVS checking tool is configured to use a first set of settings 684. For example, a setting in the first set of settings 684 for the first level of the IC device 300 and the corresponding active region layer OD1 of the IC layout 600C reads as follows:

“N/PMOS Level=1”=N/P_OD1 and N/P_PO

This setting means that when the LVS checking tool extracts a transistor (e.g., transistor M1) having a gate region pattern for N-type transistor in the gate region layer PO and an active region pattern for N-type transistor in the active region layer OD1, the LVS checking tool determines that the extracted transistor is an N-type transistor at the first level and adds “NMOS level=1” to the description of the transistor M1 in the netlist 660. When the LVS checking tool extracts transistor M1 having a gate region pattern for P-type transistor in the gate region layer PO and an active region pattern for P-type transistor in the active region layer OD1, the LVS checking tool determines that the extracted transistor is a P-type transistor at the first level and adds “PMOS level=1” to the description of the transistor M1 in the netlist 660. Other settings in the first set of settings 684 are similarly used by the LVS checking tool to extract transistors and their levels, and add corresponding descriptions and label features to the netlist 660.

To generate a layout netlist (same as the netlist 360) in accordance with the second netlist format 246, the LVS checking tool is configured to use a second set of settings (not shown). For example, a setting in the second set of settings for the first level of the IC device 300 and the corresponding active region layer OD1 of the IC layout 600C reads as follows:

“NMOS_1/PMOS_1”=N/P_OD1 AND N/P_PO

This setting is used by the LVS checking tool in a manner similar to the corresponding setting in the first set of settings 684, except that instead of adding “NMOS level=1” or “PMOS level=1” to the description of the transistor M1 in the layout netlist, the LVS checking tool correspondingly adds “NMOS_1” or “PMOS_1”. Other settings in the second set of settings are similarly configured and used by the LVS checking tool to extract transistors and their levels, and add corresponding descriptions and label features to the layout netlist in accordance with the second netlist format 246. In some embodiments, one or more advantages described herein are achievable by IC layouts, e.g., the IC layouts 600A-600C, generated in accordance with the third layout design method 233, and/or by layout netlists corresponding to such IC layouts and generated in accordance with the first netlist format 245 or the second netlist format 246.

FIG. 7 includes an example IC layout 700 and an example netlist 760 corresponding to the circuit region of the IC device 300 described with respect to FIG. 3, in accordance with some embodiments. Components in FIG. 7 having corresponding components in one or more of the other figures are designated by the same reference numerals as in the other figures. In some embodiments, the IC layout 700 corresponds to the IC layout 230, is generated by an APR tool, and/or is output from the APR tool in the form of the GDS file 235. The IC layout 700 is an example of an IC layout generated in accordance with the fourth layout design method 234, in one or more embodiments.

In the fourth layout design method 234, an IC layout is generated in accordance with a combination of at least two of the layout design methods described with respect to FIGS. 4A-4D, 5A-5B, 6A-6C. As a result, in one or more embodiments, it is possible to achieve a combination of one or more advantages related to resource management provided by the first layout design method 231 and/or the second layout design method 232 with one or more advantages related to design flexibility provided by the third layout design method 233.

In the example configuration in FIG. 7, the IC layout 700 is generated in accordance with a combination of the first layout design method 231, the second layout design method 232, and the third layout design method 233 in the situation described with respect to FIG. 6A. Other combinations of two or more of the layout design methods described with respect to FIGS. 4A-4D, 5A-5B, 6A-6C are within the scopes of various embodiments.

Specifically, in the IC layout 700, the transistors M1, M2 have corresponding active region patterns and gate region patterns different from each other, and also different from the other transistors M3-M6. Each of the transistors M1, M2 is represented in the IC layout 700 in accordance with the third layout design method 233 in the situation described with respect to FIG. 6A. For example, the transistor M1 is represented by an active region pattern 711 in the active region layer OD1 and a gate region pattern 712 in the gate region layer PO1. The transistor M2 is represented by an active region pattern (not shown for simplicity) in the active region layer OD2 and a gate region pattern (not shown for simplicity) in the gate region layer PO2. The presence of the active region pattern 711 and the gate region pattern 712 of the transistor M1 correspondingly in the active region layer OD1 and the gate region layer PO1 serves as a label feature included in the IC layout 700 to indicate the corresponding level, e.g., the first level, of the transistor M1. Similarly, the presence of the active region pattern and the gate region pattern of the transistor M2 correspondingly in the active region layer OD2 and the gate region layer PO2 serves as a label feature included in the IC layout 700 to indicate the corresponding level, e.g., the second level, of the transistor M2.

The transistors M3-M6 have the same or common active region pattern 721 in the active region layer OD, and the same or common gate region pattern 722 in the gate region layer PO. The levels of the transistors M3, M4 are indicated by corresponding label features, i.e., frames 713, 714 in corresponding CAD layers CAD_Layer_3, CAD_Layer_4, in a manner similar to that described with respect to FIG. 4A. The levels of the transistors M5, M6 are indicated by corresponding label features, i.e., text labels which are included in corresponding text layers Text_Layer_5, Text_Layer_6, and occur in the IC layout 700 at corresponding locations marked by corresponding X-shaped symbols 715, 716, in a manner similar to that described with respect to FIG. 5A.

The GDS file including the IC layout 700 is provided to an LVS checking tool which is configured to extract, from the GDS file, transistors, connections and levels of the transistors, to generate a layout netlist, as described with respect to FIG. 2. The netlist 760 in FIG. 7 is an example layout netlist generated by the LVS checking tool from the GDS file including the IC layout 700. The netlist 760 corresponding to the IC layout 700 is generated in accordance with the first netlist format 245, and is the same as the netlist 350. In some embodiments, a layout netlist (not shown in FIG. 7) corresponding to the IC layout 700 is generated in accordance with the second netlist format 246, and is the same as the netlist 360.

To generate the netlist 760 in accordance with the first netlist format 245, the LVS checking tool is configured to use a first set of settings 780 which comprises a combination of various settings similar to those described with respect to the first sets of settings 480, 580, 680. For example, in the first set of settings 780, the first two settings for the first and second levels of the IC device 300 are similar to the corresponding settings in the first set of settings 680, the next two settings for the third and fourth levels of the IC device 300 are similar to the corresponding settings in the first set of settings 480, and the last two settings for the fifth and sixth levels of the IC device 300 are similar to the corresponding settings in the first set of settings 580.

To generate a layout netlist (same as the netlist 360) in accordance with the second netlist format 246, the LVS checking tool is configured to use a second set of settings (not shown) which comprises a combination of various settings similar to those in the second sets of settings described with respect to FIGS. 4A, 5A, 6A. For example, in the second set of settings, the first two settings for the first and second levels of the IC device 300 are similar to the corresponding settings in the second set of settings described with respect to FIG. 6A, the next two settings for the third and fourth levels of the IC device 300 are similar to the corresponding settings in the second set of settings described with respect to FIG. 4A, and the last two settings for the fifth and sixth levels of the IC device 300 are similar to the corresponding settings in the second set of settings described with respect to FIG. 5A. In some embodiments, one or more advantages described herein are achievable by IC layouts, e.g., the IC layout 700, generated in accordance with the fourth layout design method 234, and/or by layout netlists corresponding to such IC layouts and generated in accordance with the first netlist format 245 or the second netlist format 246.

In some embodiments, as described herein, only one GDS file and only one netlist are required to perform an accurate LVS check on a stacked structure of multiple semiconductor devices arranged at a plurality of levels of an IC device being designed. The described approach with various layout design methods and netlist formats, in accordance with some embodiments, is compatible with any multi-level stacked structures of semiconductor devices, regardless of the number of levels of semiconductor devices being stacked. The described approach with various layout design methods and netlist formats, in accordance with some embodiments further increases the flexibility for designers'resource management, e.g., allowing improved or optimized allocation of CAD layer resources. The described approach is easy to implement and handle, in one or more embodiments. The described approach is further applicable to all technology generations which have multi-level stacked structures of semiconductor devices, without requiring any change or revision, in at least one embodiment.

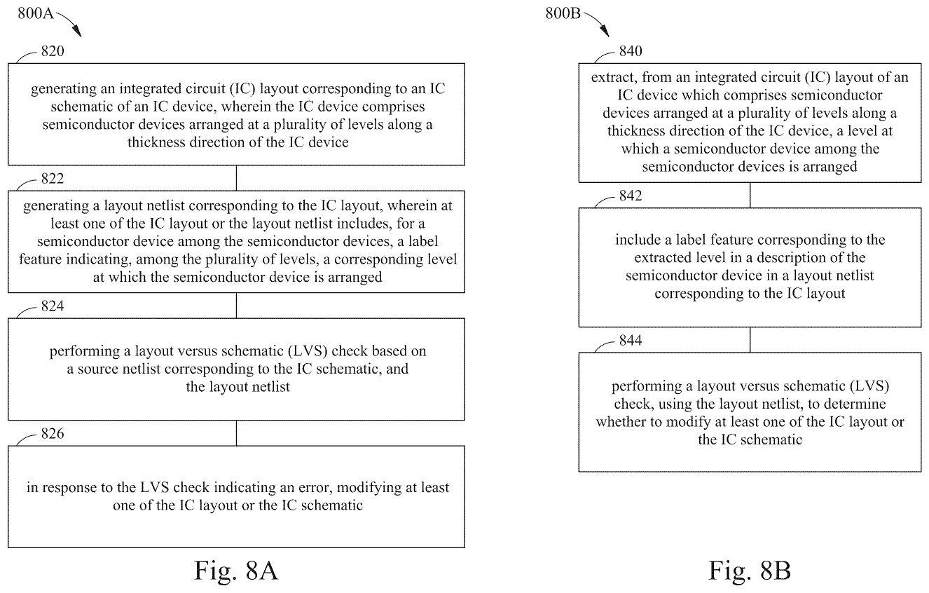

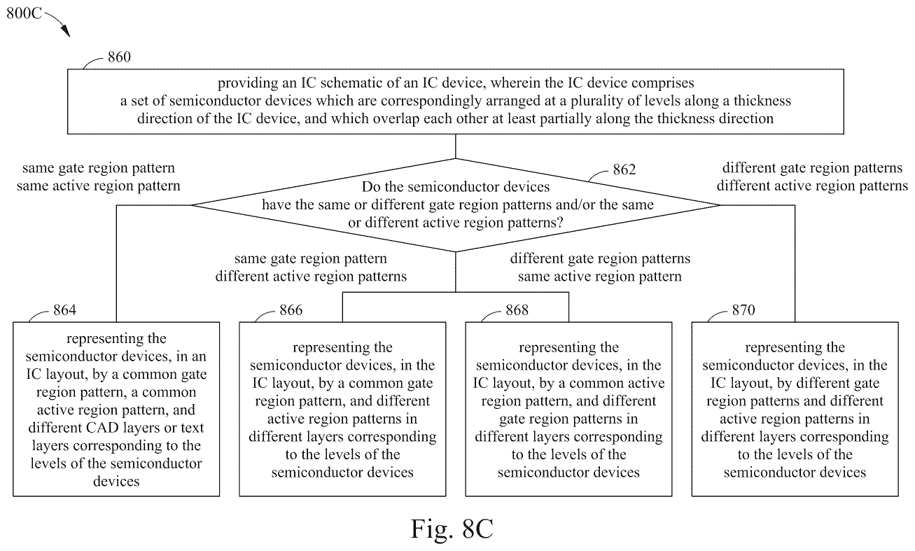

FIG. 8A is a flowchart of a method 800A, in accordance with some embodiments. In some embodiments, the method 800A is performed at least partially by at least one processor, and/or comprises at least a portion of an IC design process as described with respect to FIGS. 1, 2. The method 800A comprises operations 820, 822, 824, 826. In at least one embodiment, at least one of the operations 820, 822, 824, 826 is omitted.

At operation 820, an integrated circuit (IC) layout corresponding to an IC schematic of an IC device is generated. The IC device comprises semiconductor devices arranged at a plurality of levels along a thickness direction of the IC device. For example, as described with respect to FIGS. 2, 3, an IC layout 230 corresponding to an IC schematic 210 of an IC device 300 is generated. The IC device 300 comprises semiconductor devices (e.g., the transistors M1-M6 ) arranged at first through sixth levels along a thickness direction (e.g., the Z axis) of the IC device 300.

At operation 822, a layout netlist corresponding to the IC layout is generated. At least one of the IC layout or the layout netlist includes, for a semiconductor device among the semiconductor devices, a label feature indicating, among the plurality of levels, a corresponding level at which the semiconductor device is arranged. For example, as described with respect to FIG. 2, a layout netlist 240 corresponding to the IC layout 230 is generated. In some embodiments, the IC layout 230 includes, for a semiconductor device (e.g., the transistor M1), a label feature indicating the corresponding level (e.g., the first level) at which the transistor M1 is arranged. The label feature included in the IC layout 230 is represented in a CAD layer as described with respect to FIGS. 4A-4D, or in a text layer as described with respect to FIGS. 5A-5B, or in at least one of an active region layer or a gate region layer as described with respect to FIGS. 6A-6C. In at least one embodiment, the layout netlist 240 includes, for a semiconductor device (e.g., the transistor M1), a label feature indicating the corresponding level (e.g., the first level) at which the transistor M1 is arranged. The label feature in the layout netlist 240 is included in a description of the transistor M1 as a parameter as described with respect to the netlist 350, or as a part of a device type as described with respect to the netlist 360.

At operation 824, a layout versus schematic (LVS) check is performed based on a source netlist corresponding to the IC schematic and the layout netlist. For example, as described with respect to FIG. 2, at an LVS comparison 250, the layout netlist 240 is compared with a source netlist 220 corresponding to the IC schematic 210.

At operation 826, in response to the LVS check indicating an error, at least one of the IC layout or the IC schematic is modified. For example, as described with respect to FIG. 1, when the LVS check indicates an error, e.g., a mismatch between the source netlist 220 and the layout netlist 240, the process returns to an earlier stage to modify at least one of the IC schematic 210 or the IC layout 230. One or more advantages described herein are achievable by the method 800A, in accordance with some embodiments.

FIG. 8B is a flowchart of a method 800B, in accordance with some embodiments. In some embodiments, the method 800B is performed at least partially by at least one processor, and/or comprises at least a portion of an IC design process as described with respect to FIGS. 1, 2. The method 800B comprises operations 840, 842, 844. In at least one embodiment, at least one of the operations 840, 842, 844 is omitted.

At operation 840, a level, at which a semiconductor device among semiconductor devices of an IC device is arranged, is extracted from an integrated circuit (IC) layout of the IC device. In the IC device, the semiconductor devices are arranged at a plurality of levels along a thickness direction of the IC device. For example, as described with respect to FIGS. 2, 4A-44D, 5A-5B, 6A-6C, a level of a transistor M1 in an IC device is extracted from an IC layout of the IC device. For example, as described with respect to FIG. 4A, a level (i.e., the first level) of the transistor M1 is extracted from a CAD layer, e.g., CAD_Layer_1, of the IC layout 400A. For a further example, as described with respect to FIG. 5A, the level of the transistor M1 is extracted from a text layer, e.g., Text_Layer_1, of the IC layout 500A. For another example, as described with respect to FIGS. 6A-6C, the level of the transistor M1 is extracted from an active region layer OD1 of the IC layout 600C, or a gate region layer PO1 of the IC layout 600B, or both active region layer OD1 and gate region layer PO1 of the IC layout 600A.

At operation 842, a label feature corresponding to the extracted level is included in a description of the semiconductor device in a layout netlist corresponding to the IC layout. For example, as described with respect to FIGS. 2, 3, a label feature corresponding to the extracted level (i.e., the first level) is included in a description of the transistor M1 in a layout netlist 240, 350, 360 corresponding to the IC layout. For example, in the netlist 350, at line 355, which includes the description of the transistor M1, a label feature corresponding to the first level of the transistor M1 is added in the form of a parameter, i.e., “NMOS level=1” or “PMOS level=1”. For a further example, in the netlist 360, at line 366, which includes the description of the transistor M1, a label feature corresponding to the first level of the transistor M1 is added in the form of a part of the device type, i.e., “NMOS_1”or “PMOS_1”.

At operation 844, a layout versus schematic (LVS) check is performed, using the layout netlist, to determine whether to modify at least one of the IC layout or the IC schematic. For example, one or more operations similar to operation 824, 826 are performed. One or more advantages described herein are achievable by the method 800B, in accordance with some embodiments.

FIG. 8C is a flowchart of a method 800C, in accordance with some embodiments. In some embodiments, the method 800C is performed at least partially by at least one processor, and/or comprises at least a portion of an IC design process as described with respect to FIGS. 1, 2. The method 800C comprises operations 860, 862, 864, 866, 868, 870. In at least one embodiment, at least one of the operations 860, 862, 864, 866, 868, 870 is omitted.

At operation 860, an IC schematic of an IC device is provided. The IC device comprises a set of semiconductor devices which are correspondingly arranged at a plurality of levels along a thickness direction of the IC device, and which overlap each other at least partially along the thickness direction. For example, an IC schematic 210 of an IC device 300 is provided, as described with respect to FIGS. 2, 3. The IC device 300 comprises a set of semiconductor devices (i.e., transistors M1-M6 ) which are correspondingly arranged at first to sixth levels along a thickness direction (i.e., the Z axis) of the IC device 300. The transistors M1-M6 overlap each other at least partially along the Z axis.

At operation 862, it is determined whether the semiconductor devices have the same or different gate region patterns and/or the same or different active region patterns. In response to determining that the semiconductor devices have the same gate region pattern and the same active region pattern, e.g., as described with respect to FIGS. 4A, 5A, the process proceeds to operation 864. In response to determining that the semiconductor devices have the same gate region pattern and different active region patterns, e.g., as described with respect to FIG. 6C, the process proceeds to operation 866. In response to determining that the semiconductor devices have different gate region patterns and the same active region pattern, e.g., as described with respect to FIG. 6B, the process proceeds to operation 868. In response to determining that the semiconductor devices have different gate region patterns and different active region patterns, e.g., as described with respect to FIG. 6A, the process proceeds to operation 870.

At operation 864, the semiconductor devices are represented, in an IC layout, by a common gate region pattern, a common active region pattern, and different CAD layers or text layers corresponding to the levels of the semiconductor devices. For example, as described with respect to FIGS. 4A, 5A, the transistors M1-M6 are represented, in an IC layout 400A or 500A, by a common gate region pattern 422, a common active region pattern 421, and different CAD layers CAD_Layer_1 to CAD_Layer_6, or text layers Text_Layer_1 to Text_Layer_6 corresponding to the first to sixth levels of the transistors M1-M6.

At operation 866, the semiconductor devices are represented, in an IC layout, by a common gate region pattern, and different active region patterns in different layers corresponding to the levels of the semiconductor devices. For example, as described with respect to FIG. 6C, the transistors M1-M6 are represented, in an IC layout 600C, by a common gate region pattern 650, and different active region patterns (e.g., 651-654) in different layers OD1 to OD6 corresponding to the first to sixth levels of the transistors M1-M6.

At operation 868, the semiconductor devices are represented, in an IC layout, by a common active region pattern, and different gate region patterns in different layers corresponding to the levels of the semiconductor devices. For example, as described with respect to FIG. 6B, the transistors M1-M6 are represented, in an IC layout 600B, by a common active region pattern 640, and different gate region patterns (e.g., 641-644) in different layers PO1 to PO6 corresponding to the first to sixth levels of the transistors M1-M6.

At operation 870, the semiconductor devices are represented, in an IC layout, by different gate region patterns and different active region patterns in different layers corresponding to the levels of the semiconductor devices. For example, as described with respect to FIG. 6A, the transistors M1-M6 are represented, in an IC layout 600A, by different gate region patterns (e.g., 631-633) and different active region patterns (e.g., 621-623) in different layers PO1 and OD1 to PO6 and OD6 corresponding to the first to sixth levels of the transistors M1-M6.

In some embodiments, a combination of at least two of operations 864, 866, 868, 870 is performed to represent a set of stacked semiconductor devices, e.g., as described with respect to FIG. 7. One or more advantages described herein are achievable by the method 800C, in accordance with some embodiments.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

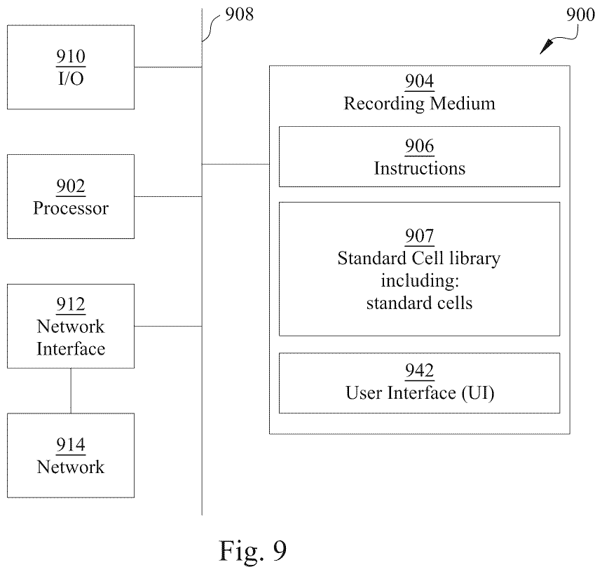

FIG. 9 is a block diagram of an electronic design automation (EDA) system 900 in accordance with some embodiments.

In some embodiments, EDA system 900 includes an APR system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable recording medium 904. Recording medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable recording medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable recording medium 904 are capable of connecting to external elements via network 914. Processor 902 is configured to execute computer program code 906 encoded in computer-readable recording medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable recording medium 904 is an electronic, magnetic, optical, electromagnetic, infrared, and/or a semiconductor system (or apparatus or device). For example, computer-readable recording medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 904 includes a compact disk-read only memory (CD-ROM), a compact disk-read/write (CD-R/W), and/or a digital video disc (DVD).

In one or more embodiments, recording medium 904 stores computer program code 906 configured to cause system 900 (where such execution represents (at least in part) the EDA tool) to be usable for performing a portion or all of the noted processes and/or methods. In one or more embodiments, recording medium 904 also stores information which facilitates performing a portion or all of the noted processes and/or methods. In one or more embodiments, recording medium 904 stores library 907 of standard cells including such standard cells as disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a UI through I/O interface 910. The information is stored in computer-readable recording medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

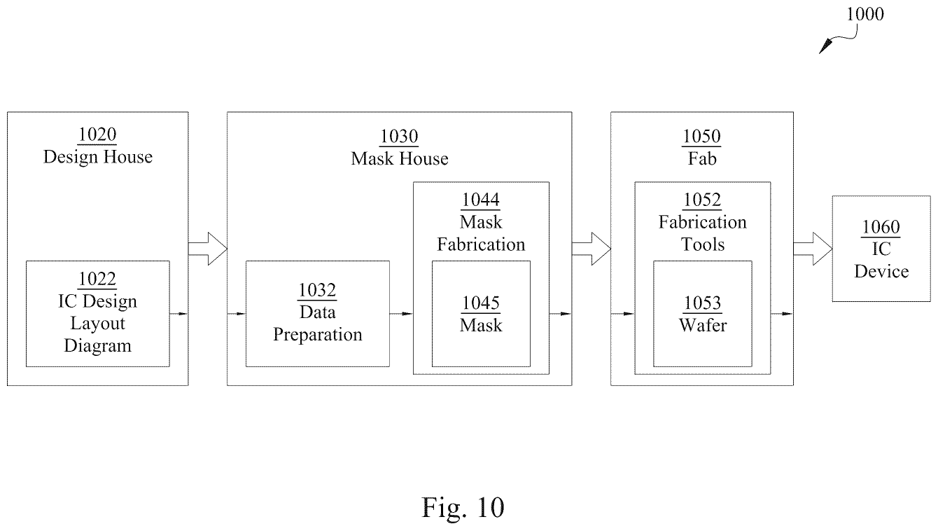

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place-and-route operation. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, a method is executed at least partially by at least one processor and comprises generating an integrated circuit (IC) layout corresponding to an IC schematic of an IC device. The IC device comprises semiconductor devices arranged at a plurality of levels along a thickness direction of the IC device. The IC layout includes, for a semiconductor device among the semiconductor devices, a label feature indicating, among the plurality of levels, a corresponding level at which the semiconductor device is arranged. The method further comprises generating a layout netlist corresponding to the IC layout, performing a layout versus schematic (LVS) check based on a source netlist corresponding to the IC schematic and the layout netlist, and modifying at least one of the IC layout or the IC schematic in response to the LVS check indicating an error.

In some embodiments, a system comprises at least one processor configured to generate an integrated circuit (IC) layout corresponding to an IC schematic of an IC device, and generate a layout netlist corresponding to the IC layout. The IC device comprises semiconductor devices arranged at a plurality of levels along a thickness direction of the IC device. The layout netlist includes, for a semiconductor device among the semiconductor devices, a label feature indicating, among the plurality of levels, a corresponding level at which the semiconductor device is arranged. The at least one processor is further configured to perform a layout versus schematic (LVS) check to determine whether to modify at least one of the IC layout or the IC schematic, based on a source netlist corresponding to the IC schematic and the layout netlist.

In some embodiments, a computer program product comprises a non-transitory, computer-readable medium containing instructions therein which, when executed by at least one processor, cause the at least one processor to extract, from an integrated circuit (IC) layout of an IC device which comprises semiconductor devices arranged at a plurality of levels along a thickness direction of the IC device, a level at which a semiconductor device among the semiconductor devices is arranged. The at least one processor is further caused to include a label feature corresponding to the extracted level in a description of the semiconductor device in a layout netlist corresponding to the IC layout, and perform a layout versus schematic (LVS) check, using the layout netlist, to determine whether to modify at least one of the IC layout or the IC schematic.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, said method executed at least partially by at least one processor and comprising:
generating an integrated circuit (IC) layout corresponding to an IC schematic of an IC device, wherein
the IC device comprises semiconductor devices arranged at a plurality of levels along a thickness direction of the IC device, and
the IC layout includes, for a semiconductor device among the semiconductor devices, a label feature indicating, among the plurality of levels, a corresponding level at which the semiconductor device is arranged;
generating a layout netlist corresponding to the IC layout;
performing a layout versus schematic (LVS) check based on
a source netlist corresponding to the IC schematic, and
the layout netlist; and
in response to the LVS check indicating an error, modifying at least one of the IC layout or the IC schematic.

2. The method of claim 1, wherein
the IC layout includes, for each semiconductor device among the semiconductor devices, a label feature indicating, among the plurality of levels, a corresponding level at which said each semiconductor device is arranged.

3. The method of claim 1, wherein
the label feature is represented by:
a computer assisted design (CAD) layer, or
a text layer, or
at least one of a gate region pattern of the semiconductor device, or an active region pattern of the semiconductor device.

4. The method of claim 1, wherein
the semiconductor devices comprises a set of semiconductor devices which overlap each other at least partially along the thickness direction, and each of which is arranged at a level among the plurality of levels, and
the IC layout includes, for each semiconductor device in the set of semiconductor devices, a label feature indicating the level at which said each semiconductor device is arranged.

5. The method of claim 4, wherein
the IC layout comprises a gate region pattern and an active region pattern which are common for the semiconductor devices in the set of semiconductor devices, and
the label features of the semiconductor devices in the set of semiconductor devices are included in different computer assisted design (CAD) layers corresponding to the levels at which the semiconductor devices in the set of semiconductor devices are correspondingly arranged.

6. The method of claim 5, wherein
the gate region pattern and the active region pattern are correspondingly in further CAD layers different from the CAD layers corresponding to the levels at which the semiconductor devices in the set of semiconductor devices are correspondingly arranged.

7. The method of claim 4, wherein
the IC layout comprises a gate region pattern and an active region pattern which are common for the semiconductor devices in the set of semiconductor devices, and
the label features of the semiconductor devices in the set of semiconductor devices are included in different text layers corresponding to the levels at which the semiconductor devices in the set of semiconductor devices are correspondingly arranged.

8. The method of claim 7, wherein
the gate region pattern and the active region pattern are correspondingly in different computer assisted design (CAD) layers.

9. The method of claim 4, wherein
the IC layout comprises:
a gate region pattern which is common for the semiconductor devices in the set of semiconductor devices, and
different active region patterns correspondingly for the semiconductor devices in the set of semiconductor devices, and
the label features of the semiconductor devices in the set of semiconductor devices are represented by the different active region patterns which are correspondingly arranged in different layers.

10. The method of claim 9, wherein
the gate region pattern and the different active region patterns are correspondingly in different computer assisted design (CAD) layers.

11. The method of claim 4, wherein
the IC layout comprises:
an active region pattern which is common for the semiconductor devices in the set of semiconductor devices, and
different gate region patterns correspondingly for the semiconductor devices in the set of semiconductor devices, and
the label features of the semiconductor devices in the set of semiconductor devices are represented by the different gate region patterns which are correspondingly arranged in different layers.

12. The method of claim 11, wherein
the active region pattern and the different gate region patterns are correspondingly in different computer assisted design (CAD) layers.

13. The method of claim 4, wherein
the IC layout comprises different active region patterns and different gate region patterns correspondingly for the semiconductor devices in the set of semiconductor devices, and
the label features of the semiconductor devices in the set of semiconductor devices comprise are represented by the different active region patterns and the different gate region patterns which are correspondingly arranged in different layers.

14. The method of claim 13, wherein
the different active region patterns and the different gate region patterns are correspondingly in different computer assisted design (CAD) layers.

15. The method of claim 4, wherein the set of semiconductor devices comprises at least two selected from the group consisting of:
a first pair of semiconductor devices for which the IC layout comprises a common gate region pattern and a common active region pattern, and the label features of the first pair of semiconductor devices are included in different computer assisted design (CAD) layers corresponding to the levels at which the first pair of semiconductor devices are correspondingly arranged,
a second pair of semiconductor devices for which the IC layout comprises a common gate region pattern and a common active region pattern, and the label features of the second pair of semiconductor devices are included in different text layers corresponding to the levels at which the second pair of semiconductor devices are correspondingly arranged,
a third pair of semiconductor devices for which the IC layout comprises a common gate region pattern and corresponding different active region patterns, and the label features of the third pair of semiconductor devices are represented by the different active region patterns which are correspondingly arranged in different CAD layers,
a fourth pair of semiconductor devices for which the IC layout comprises a common active region pattern and corresponding different gate region patterns, and the label features of the fourth pair of semiconductor devices are represented by the different gate region patterns which are correspondingly arranged in different CAD layers, and
a fifth pair of semiconductor devices for which the IC layout correspondingly comprises different gate region patterns and different active region patterns, and the label features of the fifth pair of semiconductor devices are represented by the different gate region patterns and the different active region patterns which are correspondingly arranged in different CAD layers.

16. A system, comprising at least one processor configured to:
generate an integrated circuit (IC) layout corresponding to an IC schematic of an IC device, wherein
the IC device comprises semiconductor devices arranged at a plurality of levels along a thickness direction of the IC device;
generate a layout netlist corresponding to the IC layout, wherein
the layout netlist includes, for a semiconductor device among the semiconductor devices, a label feature indicating, among the plurality of levels, a corresponding level at which the semiconductor device is arranged; and
perform a layout versus schematic (LVS) check to determine whether to modify at least one of the IC layout or the IC schematic, based on
a source netlist corresponding to the IC schematic, and
the layout netlist.

17. The system of claim 16, wherein
the layout netlist includes, for each semiconductor device among the semiconductor devices, a label feature indicating, among the plurality of levels, a corresponding level at which said each semiconductor device is arranged.

18. The system of claim 16, wherein
the label feature is included, in a description of the semiconductor device in the layout netlist, as:
a part of a device type of the semiconductor device, or
a parameter indicating the corresponding level at which the semiconductor device is arranged.

19. The system of claim 16, wherein
n is a natural number and is an index of the corresponding level at which the semiconductor device is arranged, and
a description of the semiconductor device in the layout netlist includes:
a parameter “level=n” which is the label feature, or
a device type “NMOS_n” where the semiconductor device is an N-channel metal-oxide semiconductor (NMOS) transistor, or a device type “PMOS_n” where the semiconductor device is a P-channel metal-oxide semiconductor (PMOS) transistor, wherein “n” in the device type “NMOS_n” or the device type “PMOS_n” is the label feature.

20. A computer program product, comprising a non-transitory, computer-readable medium containing instructions therein which, when executed by at least one processor, cause the at least one processor to:
extract, from an integrated circuit (IC) layout of an IC device which comprises semiconductor devices arranged at a plurality of levels along a thickness direction of the IC device, a level at which a semiconductor device among the semiconductor devices is arranged;
include a label feature corresponding to the extracted level in a description of the semiconductor device in a layout netlist corresponding to the IC layout; and
perform a layout versus schematic (LVS) check, using the layout netlist, to determine whether to modify at least one of the IC layout or the IC schematic.
